(19) United States
(12) Patent Application Publication
(10) Pub. No.: US 2026/0363050 A1
(43) Pub. Date: Nov. 12, 2026

(54) SEMICONDUCTOR DEVICE WITH MULTIPLE CONDUCTORS IN A SINGLE VIA

(71) Applicant: Samsung Electronics Co., Ltd., Suwon-si (KR)

(72) Inventors: Deokhwan Kim, Suwon-si (KR); Ho Young Kang, Suwon-si (KR); Kyung Yong Ko, Suwon-si (KR); Kyoungwoo Lee, Suwon-si (KR); Minseung Lee, Suwon-si (KR); Junhee Lee, Suwon-si (KR); Jegwan Hwang, Suwon-si (KR)

(21) Appl. No.: 19/456,765

(22) Filed: Jan. 22, 2026

(30) Foreign Application Priority Data
May 12, 2025 (KR) 10-2025-0061180

(51) Int. Cl. H10W 20/20; H10D 30/00; H10D 30/43; H10D 62/10; H10D 62/13; H10D 64/23; H10D 84/83; H10D 30/01; H10D 84/01; H10W 20/41

(52) U.S. Cl. CPC H10W 20/2128; H10D 30/43; H10D 30/502; H10D 62/121; H10D 62/151; H10D 64/256; H10D 84/832; H10W 20/2134; H10W 20/216; H10D 30/014; H10D 30/019; H10D 84/0149; H10W 20/435

(57) ABSTRACT

A semiconductor device has a substrate including a first surface and a second surface facing each other, source/drain patterns spaced apart on the first surface of the substrate, a channel pattern connecting the source/drain patterns, a gate electrode surrounding the channel pattern, a lower wiring structure on the second surface of the substrate, a through via hole extending through the substrate to reach the lower wiring structure, a first through via and a second through via within the through via hole and connected to the lower wiring structure, respectively, and an insulating structure between the first through via and the second through via, wherein, in a cross-section a width of the insulating structure increases as a distance from the lower wiring structure increases.

### CROSS-REFERENCE TO RELATED APPLICATIONS

This application claims priority to and the benefit of Korean Patent Application No. 10-2025-0061180 filed with the Korean Patent Office on May 12, 2025, the entire contents of which are incorporated herein by reference.

### BACKGROUND

The present disclosure relates to a semiconductor device.

A semiconductor is a material that belongs to the intermediate region between conductors and insulators, and is a material that conducts electricity under certain conditions. Using these semiconductor materials, various semiconductor devices may be manufactured, such as memory elements. These semiconductor devices may be used in a variety of electronic devices.

As the electronics industry develops, the demands on the characteristics of semiconductor devices are increasing. For example, there is an increasing demand for high reliability, high speed, and/or multi-functionality in semiconductor devices. To meet these demanding characteristics, structures within semiconductor devices are becoming increasingly complex and integrated.

### SUMMARY

The implementations provide a semiconductor device that suppresses signal interference and alleviates process difficulty by forming an insulating structure within the same trench to reduce parasitic capacitance between through vias transmitting different signals or power.

According to some implementations, a semiconductor device comprises a substrate including a first surface and a second surface facing each other, source/drain patterns spaced apart in a first direction on the first surface of the substrate, a channel pattern connecting the source/drain patterns, a gate electrode surrounding the channel pattern and extending in a second direction intersecting the first direction, a lower wiring structure disposed on the second surface of the substrate, a through via hole extending through the substrate in a third direction intersecting the first and second directions to reach the lower wiring structure, a first through via and a second through via disposed within the through via hole and connected to the lower wiring structure, respectively, and an insulating structure disposed between the first through via and the second through via, wherein, in a cross-section taken along the first and third directions, a width of the insulating structure increases as a distance from the lower wiring structure increases.

According to some implementations, a semiconductor device comprises a substrate including a first surface and a second surface facing each other, source/drain patterns spaced apart in a first direction on the first surface of the substrate, a channel pattern connecting the source/drain patterns, a gate electrode surrounding the channel pattern and extending in a second direction intersecting the first direction, a lower wiring structure disposed on the second surface of the substrate, a through via hole extending through the substrate in a third direction intersecting the first and second directions to reach the lower wiring structure, a first through via and a second through via disposed inside the through via hole and respectively connected to the lower wiring structure, and an insulating structure disposed between the first through via and the second through via, wherein the insulating structure includes a first liner and a second liner respectively contacting the first through via and the second through via, and, in a cross-section taken along the first and third directions, a distance between the first liner and the second liner increases as a distance from the lower wiring structure increases.

According to some implementations, a semiconductor device comprises a substrate including a first surface and a second surface facing each other, source/drain patterns spaced apart in a first direction on the first surface of the substrate, a channel pattern connecting the source/drain patterns, a gate electrode surrounding the channel pattern and extending in a second direction intersecting the first direction, a lower wiring structure disposed on the second surface of the substrate, a first through via hole and a second through via hole respectively extending through the substrate in a third direction intersecting the first and second directions to reach the lower wiring structure, a first through via and a second through via disposed inside the first through via hole and respectively connected to the lower wiring structure, a third through via and a fourth through via disposed inside the second through via hole and respectively connected to the lower wiring structure, and a first insulating structure disposed between the first through via and the second through via and a second insulating structure disposed between the third through via and the fourth through via, wherein a first width of the first insulating structure is different from a second width of the second insulating structure.

According to some implementations, a method of manufacturing a semiconductor device comprises forming a stacked pattern comprising alternating active layers and sacrificial layers on a substrate, forming a sacrificial pattern extending in one direction on the stacked pattern, forming a recess in the stacked pattern, wherein the active layers include a plurality of channel patterns exposed by the recess, forming source/drain patterns that fill the recess, forming an interlayer insulating layer over the source/drain patterns and the substrate, removing the sacrificial pattern and the sacrificial layers to expose the plurality of channel patterns, forming a gate structure by sequentially depositing a gate insulating film and a gate electrode on the exposed plurality of channel patterns, forming a through via hole penetrating the interlayer insulating layer, and forming an insulating structure within the through via hole, and a first through via and a second through via positioned on respective sides of the insulating structure.

According to some implementations, in the method of manufacturing a semiconductor device, the first through via and the second through via may be formed after the insulating structure is formed.

According to some implementations, in the method of manufacturing a semiconductor device, the insulating structure may have an inverted taper shape in which a horizontal width increases as a distance from an upper surface of the substrate increases.

According to some implementations, in the method of manufacturing a semiconductor device, forming the insulating structure may include forming a liner material layer on an inner surface of the through via hole, forming a dummy material layer over the liner material layer so as to fill the through via hole, forming a trench within the dummy material layer, and forming the insulating structure within the trench.

According to some implementations, in the method of manufacturing a semiconductor device, the liner material layer may include an oxide, the dummy material layer may include a spin-on hardmask (SOH), and the insulating structure may include silicon oxide.

According to some implementations, in the method of manufacturing a semiconductor device, forming the first through via and the second through via may include removing the dummy material layer, and forming the first through via and the second through via in a space from which the dummy material layer has been removed.

According to some implementations, in the method of manufacturing a semiconductor device, removing a portion of the substrate from a lower surface of the substrate, and forming a lower wiring structure in a region where the substrate has been removed, the lower wiring structure being respectively connected to the first and second through vias.

According to some implementations, in the method of manufacturing a semiconductor device, forming the insulating structure may include forming an insulating liner on the trench, forming an oxide material layer in the trench, removing the dummy material layer and forming the first through via and the second through via in a space from which the dummy material layer has been removed, forming a hard mask pattern including a first opening on a front surface of the substrate, removing at least a portion of the oxide material layer using the hard mask pattern as an etch mask, and forming a low-k dielectric layer in a space from which the oxide material layer has been removed.

According to some implementations, in the method of manufacturing a semiconductor device, an air gap may be formed in the low-k dielectric layer.

### BRIEF DESCRIPTION OF THE DRAWINGS

FIG. 1 is a cross-sectional view of a semiconductor device according to some implementations.

FIGS. 2 to 4 are plan views showing through via holes of semiconductor devices according to some implementations.

FIGS. 5 to 14 are cross-sectional views for explaining a method of manufacturing a semiconductor device according to some implementations.

FIG. 15 is a plan view showing through via holes of a semiconductor device according to some implementations.

FIG. 16 is a cross-sectional view of a semiconductor device according to some implementations.

FIG. 17 is a plan view showing a through via hole of a semiconductor device according to some implementations.

FIG. 18 is a cross-sectional view of a semiconductor device according to some implementations.

FIG. 19 is a cross-sectional view of a semiconductor device according to some implementations.

FIG. 20 is a cross-sectional view of a semiconductor device according to some implementations.

FIG. 21 is a plan view showing a through via hole of a semiconductor device according to some implementations.

FIG. 22 is a cross-sectional view of a semiconductor device according to some implementations.

FIGS. 23 to 30 are cross-sectional views illustrating a method for manufacturing a semiconductor device according to some implementations.

### DETAILED DESCRIPTION

Hereinafter, various implementations of the present disclosure will be described in detail with reference to the attached drawings so that a person having ordinary skill in the art to which the present disclosure pertains may easily implement the disclosure. The present disclosure may be embodied in many different forms and is not limited to the implementations described herein.

In order to clearly explain the present disclosure, parts irrelevant to the description are omitted, and the same reference numerals are used for identical or similar components throughout the specification.

In addition, the size and thickness of each component shown in the drawing are arbitrarily shown for convenience of explanation, so the present disclosure is not necessarily limited to what is shown. To clearly represent the various layers and areas in the drawing, the thickness is enlarged and shown. And in the drawing, for convenience of explanation, the thickness of some layers and areas is exaggerated.

Also, when we say that a part, such as a layer, membrane, region, or plate, is "over" or "on" another part, this includes not only cases where it is "directly over" the other part, but also cases where there are other parts in between. Conversely, when we say that a part is "directly above" another part, we mean that there is no other part in between. Also, being "above" or "on" a reference part means being located above or below the reference part and does not necessarily mean being located "above" or "on" the opposite direction of gravity.

Additionally, throughout the specification, whenever a part is said to "include" a component, this does not mean that it excludes other components, but rather that it may include other components, unless otherwise specifically stated.

Additionally, throughout the specification, when we say "in plan", we mean when the target portion is viewed from above, and when we say "in cross section", we mean when the target portion is viewed from the side in a cross-section cut vertically.

Additionally, throughout the specification, two directions parallel to and intersecting with the upper surface of the substrate are defined as a first direction D1 and a second direction D2, respectively, and the direction perpendicular to the upper surface of the substrate is described as a third direction D3. For example, the first direction D1 and the second direction D2 may be orthogonal to each other.

Additionally, throughout the specification, the upper surface of the substrate may be referred to as the first surface of the substrate, and the lower surface of the substrate may be referred to as the second surface of the substrate.

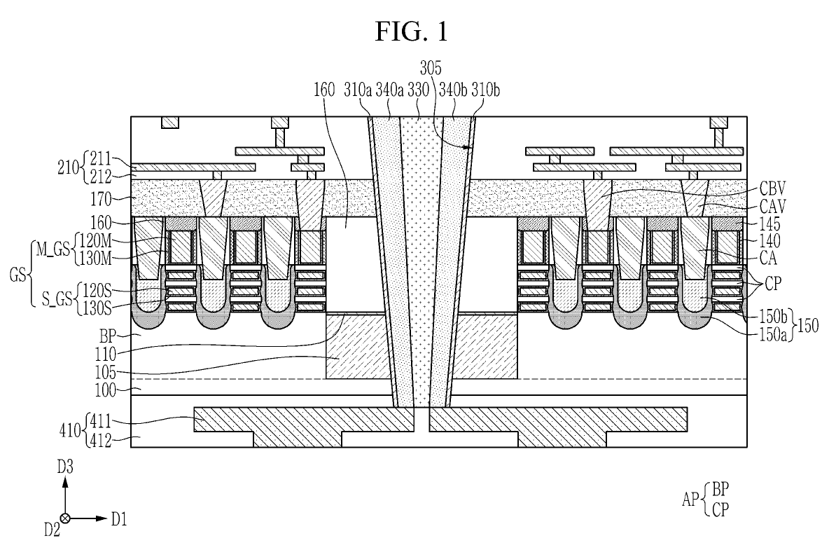

Hereinafter, a semiconductor device according to some implementations will be described in detail with reference to FIG. 1.

FIG. 1 is a cross-sectional view of a semiconductor device according to some implementations.

In FIG. 1, a transistor including nanowires or nanosheets, a MBCFET^{TM} (Multi-Bridge Channel Field Effect Transistor) is illustrated as an example, but is not limited thereto. It should be noted that semiconductor devices according to some implementations may include a fin field effect transistor (FinFET), a tunneling FET, a 3D stack field effect transistor (3DSFET), or a complementary field effect transistor (CFET).

Referring to FIG. 1, a logic cell may be provided on a substrate 100. Logic transistors that constitute a logic circuit may be placed on a logic cell.

According to some implementations, the upper surface of the substrate 100 may be formed as a plane parallel to a first direction D1 and a second direction D2 intersecting the first direction D1.

For example, the substrate 100 may be a semiconductor substrate including silicon, germanium, or silicon-germanium, or a compound semiconductor substrate. As another example, the substrate 100 may be an insulating substrate including an insulating material.

According to some implementations, the active pattern AP may be portions protruding from the substrate 100 in a third direction D3. The active patterns AP may be spaced apart in the second direction D2. The active pattern AP may extend in the first direction D1.

In some implementations, the active pattern AP may be located in a region where either an NMOS or a PMOS is formed. In some implementations, the active pattern AP may include a lower pattern BP and a channel pattern CP.

According to some implementations, the lower pattern BP may be formed by etching a portion of the substrate 100 or may include an epitaxial layer grown from the substrate 100. The lower pattern BP may include an elemental semiconductor material such as silicon (Si) or germanium (Ge). Additionally, the lower pattern BP may include a compound semiconductor, for example, a group IV-IV compound semiconductor or a group III-V compound semiconductor.

The IV-IV group compound semiconductor may be, for example, a binary compound or ternary compound containing at least two or more of carbon (C), silicon (Si), germanium (Ge), and tin (Sn).

The III-V group compound semiconductor may be, for example, a binary compound, a ternary compound, or a quaternary compound formed by combining at least one of aluminum (Al), gallium (Ga), and indium (In), which are group III elements, with one of phosphorus (P), arsenic (As), and antimony (Sb), which are group V elements.

However, this disclosure is not limited to the above, and in some cases, the lower pattern BP may be formed of an insulating pattern including an insulating material.

According to some implementations, the channel pattern CP may have a nanosheet shape and may be a semiconductor pattern including a semiconductor material. According to some implementations, the channel patterns CP may be positioned spaced apart in the first direction D1.

According to some implementations, the channel pattern CP may be located on the upper surface of the lower pattern BP. The channel pattern CP may be spaced apart from the lower pattern BP in a third direction D3. Multiple channel patterns CP may be spaced apart from each other in a third direction D3 above the lower pattern BP. Specifically, the channel patterns CP may be spaced apart from each other in the third direction D3 with the sub-gate electrodes 120S (described below) therebetween. In some implementations, the distances between channel patterns CP may all be equal, but are not limited thereto.

In FIG. 1, three channel patterns CP are illustrated as being stacked and spaced apart along the third direction D3, but this disclosure is not limited thereto. For example, two channel patterns CP may be stacked spaced apart along the third direction D3, or four or more channel patterns CP may be stacked spaced apart along the third direction D3.

In addition, for example, in FIG. 1, the side surfaces of the channel patterns CP are depicted as being curved, but this disclosure is not limited thereto. For example, the side surfaces of the channel patterns CP may be a combination of curved and flat surfaces or may be entirely flat.

Additionally, for example, the channel patterns CP may have a pin-shaped pattern shape rather than a nanosheet shape. For example, the pin-shaped pattern shape may be a shape that protrudes in the third direction D3 from the upper portion of the lower pattern BP.

The channel pattern CP may include one of the elemental semiconductor materials, silicon (Si) or silicon germanium (SiGe), a group IV-IV compound semiconductor, or a group III-V compound semiconductor. The channel pattern CP may contain the same material as the lower pattern BP or may contain a different material from the lower pattern BP.

For example, the lower pattern BP and the channel pattern CP may include silicon (Si). As another example, the lower pattern BP and the channel pattern CP may include silicon germanium (SiGe). As another example, the lower pattern BP may include silicon (Si), and the channel pattern CP may include silicon germanium (SiGe).

According to some implementations, the semiconductor device may further include a field insulating layer 105.

According to some implementations, the field insulating layer 105 may be positioned on the substrate 100. A field insulating layer 105 positioned on a portion of a substrate 100 may include at least a portion of a through via hole 305. In other words, the field insulating layer 105 positioned on a portion of the substrate 100 may surround at least a portion of the through via hole 305.

A field insulating layer 105 positioned on another area of the substrate 100 may be positioned on the lower pattern BP. The field insulating layer 105 may be located on the sidewall of the lower pattern BP. The field insulating layer 105 may not be located on the upper surface of the lower pattern BP. The field insulating layer 105 may cover a portion of the side wall of the lower pattern BP. In such a case, a part of the lower pattern BP may protrude in the third direction D3 from the upper surface of the field insulating layer 105. The field insulating layer 105 may entirely cover the side surface of the lower pattern BP.

The field insulating layer 105 may include, for example, an oxide, a nitride, a nitride oxide, or a combination thereof. The field insulating layer 105 is illustrated as a single film, but this is only for convenience of explanation and is not limited thereto.

According to some implementations, the semiconductor device may further include an etch stop layer 110 positioned on the field insulating layer 105.

The etch stop layer 110 may be positioned between the field insulating layer 105 and the first interlayer insulating layer 160 described below. For example, the etch stop layer 110 may include a nitride such as SiN or AlN.

According to some implementations, the gate structure GS may be positioned on the lower pattern BP. The gate structure GS may intersect the lower pattern BP. A gate structure GS may surround a channel pattern CP. The gate structure GS may extend in the second direction D2. A plurality of gate structures GS may be positioned spaced apart in the first direction D1.

According to some implementations, the gate structure GS may include a plurality of sub-gate structures S_GS and a main gate structure M_GS.

According to some implementations, the gate structure GS may include a gate electrode 120M and 120S and a gate insulating film 130M and 130S. In the present disclosure, the gate electrode 120M and 120S may be defined as a concept including a main gate electrode 120M and a sub gate electrode 120S. Additionally, in the present disclosure, the gate insulating film 130M and 130S may be defined as a concept including a main gate insulating film 130M and a sub gate insulating film 130S.

According to some implementations, a plurality of sub-gate structures S_GS may be positioned between adjacent channel patterns CP in the third direction D3 and between a lower pattern BP and a lowermost channel pattern CP. The main gate structure M_GS may be positioned on the channel pattern CP located at the top.

Specifically, a plurality of sub-gate structures S_GS may be positioned between the upper surface of the lower pattern BP and the lower surface of the lowermost channel pattern CP, and between the upper surface of the channel pattern CP and the lower surface of the channel pattern CP facing in the third direction D3.

A plurality of sub-gate structures S_GS may be adjacent to the source/drain pattern 150. A main gate structure M_GS may be positioned on a plurality of sub-gate structures S_GS and a channel pattern CP. Specifically, the main gate structure M_GS may be located on the top channel pattern CP.

According to some implementations, the number of the plurality of sub-gate structures S_GS may be proportional to the number of channel patterns CP. For example, the number of the plurality of sub-gate structures S_GS may be equal to the number of channel patterns CP. For example, as illustrated in FIG. 1, the number of the plurality of sub-gate structures S_GS may be three. However, the number is not limited thereto, and the plurality of sub-gate structures S_GS may include four or more sub-gate structures S_GS.

According to some implementations, the sub-gate structure S_GS may include a sub-gate electrode 120S and a sub-gate insulating film 130S.

According to some implementations, the gate electrode 120M and 120S may be located on the lower pattern BP. The gate electrode 120M and 120S may surround the channel pattern CP.

the sides of the sub-gate structures S_GS and channel patterns CP may be covered by the main gate structure M_GS.

According to some implementations, at least a portion of the gate electrode 120M and 120S may be positioned on a stacked structure of the sub-gate electrode 120S and the channel patterns CP. Another part of the gate electrode 120M and 120S may be formed to cover both sides of the laminated structure of the sub-gate electrode 120S and the channel patterns CP. At this time, the four sides of the channel patterns CP may be surrounded by gate electrode 120M and 120S.

For example, the sub-gate electrode 120S may include at least one of a metal, a metal alloy, a conductive metal nitride, a metal silicide, a doped semiconductor material, a conductive metal oxide, and a conductive metal oxynitride. Specifically, for example, the sub-gate electrode 120S may be formed of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC-N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), It may include at least one of, but is not limited to, molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxides and conductive metal nitrides may include, but are not limited to, oxidized forms of the materials described above.

According to some implementations, the sub-gate insulating film 130S may surround the sub-gate electrode 120S. The sub-gate insulating film 130Smay be positioned on the channel patterns CP. For example, the sub-gate insulating film 130S may be in direct contact with the channel patterns CP. For example, the sub-gate insulating film 130S may include silicon oxide, silicon oxynitride, or silicon nitride. Or, for example, the sub-gate insulating film 130S may include a high-k material. Alternatively, for example, the sub-gate insulating film 130S may include both silicon oxide and a high-k material. High-k materials may include materials with a dielectric constant higher than silicon oxide (SiO₂), such as hafnium oxide (HfO), aluminum oxide (AlO), or tantalum oxide (TaO).

An inner spacer may be interposed between the plurality of sub-gate electrodes 120S and the source/drain pattern 150. The inner spacer may be in direct contact with the source/drain pattern 150. A plurality of sub-gate electrodes 120S may be spaced apart from the source/drain pattern 150 by inner spacers.

According to some implementations, the main gate structure M_GS may be positioned on the sub-gate structure S_GS and the channel pattern CP. Specifically, the main gate structure M_GS may be positioned on the upper surface of the uppermost channel pattern CP.

According to some implementations, the main gate structure M_GS may include a main gate electrode 120Mand a main gate insulating film 130M.

The main gate electrode 120M may be located on the sub-gate structure S_GS and the channel pattern CP. The main gate electrode 120M may be located on the upper surface of the uppermost channel pattern CP. The main gate electrode 120M may be formed integrally with the sub gate electrode 120S. The main gate electrode 120Mmay include the same material as the sub gate electrode 120S. For example, the main gate electrode 120M may include at least one of a metal, a metal alloy, a conductive metal nitride, a metal silicide, a doped semiconductor material, a conductive metal oxide, and a conductive metal oxynitride.

According to some implementations, at least some of the main gate electrodes 120M may be connected to the upper wiring structure 210 via a gate via CBV described below.

The main gate insulating film 130M may extend along the side and lower surfaces of the main gate electrode 120M. The main gate insulating film 130M may extend along the side of the gate spacer 140. For example, the main gate insulating film 130M may include silicon oxide, silicon oxynitride, or silicon nitride. Or, for example, the main gate insulating film 130Mmay include a high-k material. Or, for example, the main gate insulating film 130M may include both silicon oxide and a high-k material.

According to some implementations, the semiconductor device may further include gate spacers 140 positioned on both sides of the main gate electrode 120M.

The gate spacer 140 may be located on the outside of the main gate insulating film 130M. The main gate insulating film 130M may be positioned between the main gate electrode 120Mand the gate spacer 140. The gate spacer 140 may not be located between the main gate electrode 120M and the uppermost channel pattern CP.

According to some implementations, the gate spacer 140 may include at least one of, for example, silicon nitride (SiN), silicon oxynitride (SiON), silicon oxide (SiO₂), silicon carbonitride (SiOCN), silicon boron nitride (SiBN), silicon oxyboron nitride (SiOBN), silicon oxycarbide (SiOC), and combinations thereof. The gate spacer 140 is illustrated as a single layer, but this is only for convenience of illustrate. The gate spacer 140 is not limited thereto and may be formed of a plurality of layers.

According to some implementations, the semiconductor device may further include a source/drain pattern 150 positioned on the lower pattern BP.

The source/drain pattern 150 may be located between adjacent sub-gate structures S_GS in the first direction D1. For example, the source/drain pattern 150 may be located on both sides of the sub-gate structures S_GS.

The source/drain pattern 150 may be located on the side of the channel patterns CP. For example, the source/drain pattern 150 may be in contact with the side surfaces of the channel patterns CP. The source/drain pattern 150 may be located between adjacent channel patterns CP in the first direction D1.

In some implementations, the source/drain pattern 150 may be in contact with a side surface of the sub-gate structure S_GS.

The side of the source/drain pattern 150 may have an uneven embossed shape. In other words, the side of the source/drain pattern 150 may have a wavy profile. For example, a side surface of a source/drain pattern 150 adjacent to a sub-gate structure S_GS may have a roughly convex shape toward the sub-gate structure S_GS, and a side surface of a source/drain pattern 150 adjacent to the channel patterns CP may have a roughly concave shape toward the channel patterns CP.

According to some implementations, the source/drain patterns 150 may be epitaxial patterns formed by a selective epitaxial growth process using the active pattern AP as a seed. The source/drain pattern 150 may, according to some implementations, include at least one of silicon (Si) and silicon germanium (SiGe). The channel patterns CP may be part of an active pattern AP extending between the source/drain patterns 150. The source/drain pattern 150 may serve as the source/drain of a transistor that uses channel patterns CP as a channel region.

The source/drain pattern 150 may include a first source/drain layer 150a and a second source/drain layer 150b. The first source/drain layer 150amay have a shape that surrounds the side and lower surfaces of the second source/drain layer 150b.

The channel patterns CP may be in contact with the first source/drain layer 150aand may not be in contact with the second source/drain layer 150b. Accordingly, a first source/drain layer 150a may be positioned between the channel patterns CP and the second source/drain layer 150b.

However, the disclosre is not limited thereto, and at least some of the channel patterns CP may be in contact with the second source/drain layer 150b. Additionally, the source/drain pattern 150 may not be divided into a first source/drain layer 150a and a second source/drain layer 150b but may be formed as a single layer.

For example, the source/drain pattern 150 may include SiGe. The Ge content of the first source/drain layer 150amay be different from the Ge content of the second source/drain layer 150b.

The first source/drain layer 150a may be made of SiGe containing a low concentration of Ge, and the second source/drain layer 150b may be made of SiGe containing a high concentration of Ge. However, the material of the source/drain pattern 150 is not limited to this and may be changed in various ways.

According to some implementations, the lower surface of the source/drain pattern 150 may be located at a lower level than the lower surface of the sub-gate structure S_GS. For example, as illustrated in FIG. 1, the lower surface of the source/drain pattern 150 may be positioned closer to the bottom surface of the lower pattern BP of the substrate 100 than the lower surface of the sub-gate structure S_GS located at the bottom.

According to some implementations, the semiconductor device may further include a contact pattern CA positioned on the source/drain patterns 150.

For example, the contact pattern CA may be electrically connected to at least one of the source/drain patterns 150. A pair of contact patterns CA may be arranged with a main gate electrode 120Mbetween them. From a planar viewpoint, the contact pattern CA may have a bar shape extending in the second direction D2.

In some implementations, silicide patterns may be interposed between the contact pattern CA and the source/drain pattern 150. The contact pattern CA may be electrically connected to the source/drain pattern 150 through a silicide pattern. The silicide pattern may include a metal-silicide, for example, titanium-silicide, tantalum-silicide, tungsten-silicide, nickel-silicide, cobalt-silicide, or combinations thereof.

According to some implementations, the contact pattern CA may be connected to the upper wiring structure 210 via a contact via CAV described below.

The contact pattern CA may include a conductive pattern and a barrier pattern surrounding the conductive pattern. For example, the conductive pattern may include aluminum, copper, tungsten, molybdenum, or a combination thereof. The barrier pattern may cover the side walls and bottom surface of the conductive pattern. The barrier pattern may include a metal film or a metal nitride film. The metal film may include titanium, tantalum, tungsten, nickel, cobalt, platinum, or combinations thereof. The metal nitride film may include titanium nitride (TiN), tantalum nitride (TaN), tungsten nitride (WN), nickel nitride (NiN), cobalt nitride (CoN), platinum nitride (PtN), or a combination thereof.

According to some implementations, the first interlayer insulating layer 160 may be positioned on the substrate 100. For example, the first interlayer insulating layer 160 may be positioned on the field insulating layer 105. The first interlayer insulating layer 160 may cover the source/drain pattern 150. Additionally, the first interlayer insulating layer 160 may be positioned between the main gate electrode 120M and the contact pattern CA, for example, between the gate spacer 140 and the contact pattern CA.

According to some implementations, the first interlayer insulating layer 160 may include at least a portion of a through via hole 305 described below. In other words, the first interlayer insulating layer 160 may surround at least a portion of the through via hole 305.

For example, the first interlayer insulating layer 160 may include silicon oxide. Although the first interlayer insulating layer 160 is illustrated as a single film, it is not limited thereto, and the first interlayer insulating layer 160 may be formed of a multi-layer film in which the plurality of layers are laminated.

According to some implementations, the semiconductor device may include a second interlayer insulating layer 170 positioned on the first interlayer insulating layer 160.

For example, the second interlayer insulating layer 170 is positioned on the main gate electrode 120M and the contact pattern CA and may cover the main gate electrode 120Mand the contact pattern CA.

The second interlayer insulating layer 170 may have an upper portion and a lower portion facing in the third direction D3. The lower part of the second interlayer insulating layer 170 is located closer to the substrate 100 than the upper part. The second interlayer insulating layer 170 may have through holes opening in the third direction D3. In other words, the through holes may extend through the second interlayer insulating layer 170 from the bottom to the top in the third direction D3.

For example, the second interlayer insulating layer 170 may include silicon oxide. Although the second interlayer insulating layer 170 is illustrated as a single film, it is not limited thereto, and the second interlayer insulating layer 170 may be formed of a multi-layer film in which the plurality of layers are laminated.

According to some implementations, the semiconductor device may further include a contact via CAV and a gate via CBV positioned within each of the through holes of the second interlayer insulating layer 170.

The contact via CAV may be located on top of the contact pattern CA, and the gate via CBV may be located on top of the main gate electrode 120M. Contact vias CAV and gate vias CBV may fill the interior of the through holes in the second interlayer insulating layer 170.

For example, gate vias CBV and contact vias CAV may include aluminum, copper, tungsten, molybdenum, cobalt, or combinations thereof.

A semiconductor device according to some implementations may further include an upper wiring structure 210 positioned on a second interlayer insulating layer 170.

In some implementations, the upper wiring structure 210 may cover the upper portions of the contact via CAV and the gate via CBV.

According to some implementations, the upper wiring structure 210 may include upper wirings 211, vias, and an upper insulating layer 212. The upper wiring 211 and vias may include metal. An upper insulating layer 212 may be placed between the upper wirings 211 and vias to insulate them. The upper insulating layer 212 may cover the second interlayer insulating layer 170. The upper wiring 211 and vias may be located within the upper insulating layer 212.

The upper wiring structure 210 may be electrically connected to at least one of the main gate electrode 120M and the source/drain pattern 150.

According to some implementations, an electrical signal or power voltage supplied from the outside may be provided to the source/drain patterns 150 through the upper wiring structure 210 and the contact pattern CA connected thereto.

In some implementations, additional upper wiring structures may be positioned stacked over the upper wiring structure 210. Each of the stacked upper wiring structures may include routing wires.

For example, the upper wirings 211 and vias of the upper wiring structure 210 may include aluminum, copper, tungsten, molybdenum, cobalt, or a combination thereof.

A semiconductor device according to some implementations may further include a first lower wiring structure 410 positioned on a lower surface of the substrate 100.

According to some implementations, the first lower wiring structure 410 may cover the lower surface of the substrate 100. According to some implementations, the first lower wiring structure 410 may include a lower pad 411 and a first lower insulating layer 412.

According to some implementations, the lower pad 411 may be electrically connected to each of the first through via 340a and the second through via 340b described below. The lower pad 411 may be insulated from the substrate 100 by the first lower insulating layer 412. The first lower insulating layer 412 may be formed of a silicon oxide layer or a silicon nitride layer.

A solder bump, which is an external connection terminal, may be additionally formed on the lower pad 411 as needed. Another semiconductor device may be laminated and bonded on the lower pad 411 as needed.

According to some implementations, the semiconductor device may include a through via hole 305 extending into the first interlayer insulating layer 160 and the substrate 100. According to some implementations, the through via hole 305 may extend through the substrate 100 in the third direction D3 to the first lower wiring structure 410. Specifically, the through via hole 305 may extend through the substrate 100 in the third direction D3 to the lower pad 411 of the first lower wiring structure 410. According to some implementations, the through via hole 305 may extend sequentially through the first interlayer insulating layer 160, the etch stop layer 110, the field insulating layer 105, and the substrate 100 to the lower pad 411 of the first lower wiring structure 410, as illustrated. However, the through hole via 305 is not limited thereto and may not extend through the etch stop layer 110 and the field insulating layer 105.

According to some implementations, the semiconductor device may include a first liner 310a, a second liner 310b, a first through via 340a, and a second through via 340b positioned within a through via hole 305. According to some implementations, the semiconductor device may include an insulating structure 330 positioned between a first through via 340a and a second through via 340b within a through via hole 305.

According to some implementations, the first liner 310a and the second liner 310b may be positioned on the inner surface of the through via hole 305. The first liner 310aand the second liner 310b may extend approximately along the third direction D3 inside the through via hole 305.

According to some implementations, the first liner 310a may be positioned between the first through via 340aand the inner surface of the through via hole 305. The second liner 310bmay be positioned between the second through via 340band the inner surface of the through via hole 305. For example, the first liner 310a and the second liner 310b may include oxide.

In some implementations, the first through via 340a and the second through via 340b may be located within a single through via hole 305. Specifically, the first through via 340aand the second through via 340b may be located on the first liner 310aand the second liner 310b, respectively. The first through via 340amay be located between the first liner 310aand an insulating structure 330 described below. The second through via 340bmay be located between the second liner 310band the insulating structure 330 described below.

According to some implementations, the first through via 340a and the second through via 340b may extend in a third direction D3 within the through via hole 305. The first through via 340a and the second through via 340b may each be connected to the lower pad 411. For example, the first through via 340a and the second through via 340b may each be electrically connected to the lower pad 411.

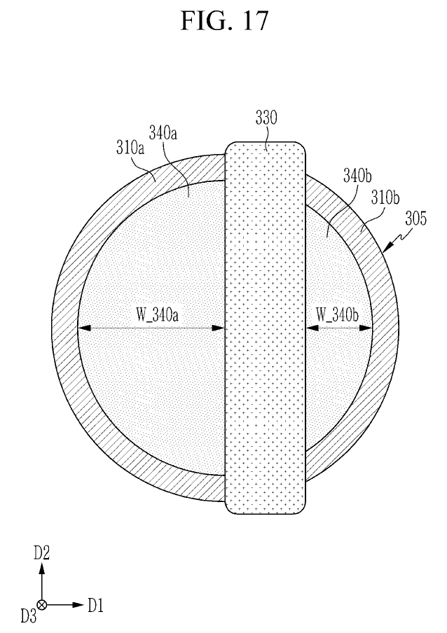

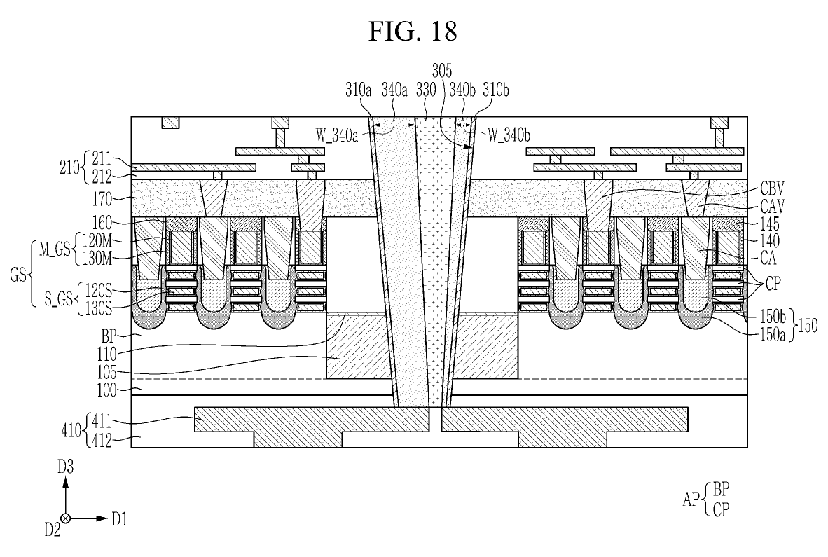

According to some implementations, the first through via 340a and the second through via 340b are separated by an insulating structure 330 described below, and thus may be used as different paths. For example, the first through via 340a and the second through via 340b may be used as paths that supply different powers. Additionally, for example, the first through via 340a and the second through via 340b may be used as paths for supplying different signals. Additionally, as described below with reference to FIGS. 17 and 18, for example, one of the first through via 340a and the second through via 340b may be used as a path for supplying power and the other may be used as a path for supplying a signal.

The first through via 340a and the second through via 340b may each include a barrier metal and a conductive pattern. The barrier metal may surround the sides and bottom of the conductive pattern. For example, the barrier metal may include, but is not limited to, at least one of tantalum (Ta), tantalum nitride (TaN), and combinations thereof. Additionally, for example, the conductive pattern may include, but is not limited to, copper (Cu).

According to some implementations, the insulating structure 330 may be positioned between the first through via 340aand the second through via 340b. The first through via 340aand the second through via 340b may be separated from each other by an insulating structure 330. Specifically, the insulating structure 330 may extend in a third direction D3 between the first through via 340a and the second through via 340b within the through via hole 305. In some implementations, the insulating structure 330, the first through via 340a and the second through via 340b may all have substantially the same upper level. The insulating structure 330 may fill the remaining area after the first liner 310a, the second liner 310b, the first through via 340a, and the second through via 340b fill the through via hole 305.

According to some implementations, the insulating structure 330 may have a reverse taper shape whose horizontal width increases as it moves away from the first lower wiring structure 410. Specifically, the horizontal width of the insulating structure 330 may increase as it gets further away from the lower surface of the first lower wiring structure 410.

For example, the insulating structure 330 may include, but is not limited to, silicon oxide (SiO₂).

As described above, in the semiconductor device according to the present disclosure, a plurality of through vias (e.g., a first through via 340aand a second through via 340b) are arranged within the same through via hole 305 with an insulating structure 330 interposed therebetween, so that the plurality of through vias positioned within the same through via hole 305 may operate independently of one another.

Specifically, the first through via 340a and the second through via 340b within the same through via hole 305 are separated by the insulating structure 330, and thus may be used as different signal transmission or power supply paths.

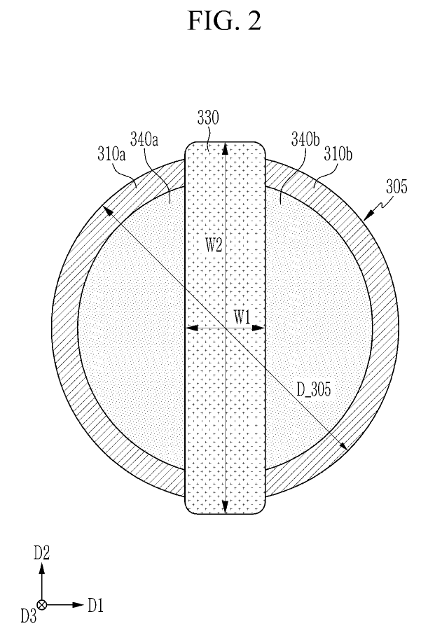

FIGS. 2 to 4 are plan views illustrating through via holes of semiconductor devices according to some implementations.

Referring to FIG. 2, a first liner 310a and a second liner 310b, a first through via 340a and a second through via 340b, and an insulating structure 330 positioned between the first through via 340a and the second through via 340b may be positioned inside a through via hole 305.

In some implementations, from a planar perspective, the through via hole 305 may have a roughly circular shape. From a planar perspective, the insulating structure 330 may have a linear shape.

In some implementations, from a planar perspective, the first liner 310a and the second liner 310b may be spaced apart along the first direction D1 by the insulating structure 330. Additionally, from a planar perspective, the first through via 340a and the second through via 340b may be spaced apart along the first direction D1 by the insulating structure 330.

According to some implementations, the insulating structure 330 may be positioned approximately at the center of the first direction D1 of the through via hole 305. Accordingly, from a planar perspective, the first through via 340a and the second through via 340b may have symmetrical shapes with respect to the insulating structure.

According to some implementations, in a planar view, the insulating structure 330 may have a first horizontal width W1 and a second horizontal width W2 that is greater than the first horizontal width W1. For example, the insulating structure 330 may have a first horizontal width W1 along a first direction D1 and a second horizontal width W2 along a second direction D2. In some implementations, the second horizontal width W2 may be larger than the diameter D_305 of the through via hole. Accordingly, the first liner 310a and the second liner 310b may be completely separated from each other by the insulating structure 330. For example, the first liner 310a and the second liner 310b may be completely separated from each other along the first direction D1 by the insulating structure 330.

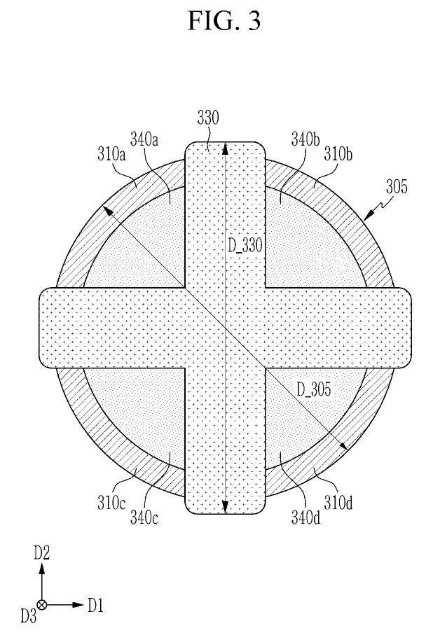

Referring to FIG. 3, an insulating structure 330 may be positioned between the first to fourth liners 310a, 310b, 310c, and 310d, the first to fourth through vias 340a, 340b, 340c, and 340d and the first to fourth through vias 340a, 340b, 340c, and 340d inside the through via hole 305.

In some implementations, from a planar perspective, the through via hole 305 may have a roughly circular shape. From a planar perspective, the insulating structure 330 may have a cross shape.

According to some implementations, in a planar view, the first liner 310a and the second liner 310b may be spaced apart along the first direction D1 by the insulating structure 330, and the third liner 310c and the fourth liner 310d may be spaced apart along the first direction D1 by the insulating structure 330. The first liner 310a and the third liner 310cmay be spaced apart along the second direction D2 by the insulating structure 330, and the second liner 310b and the fourth liner 310d may be spaced apart along the second direction D2 by the insulating structure 330.

According to some implementations, in a planar view, the first through via 340a and the second through via 340b may be spaced apart along the first direction D1 by the insulating structure 330, and the third through via 340c and the fourth through via 340d may be spaced apart along the first direction D1 by the insulating structure 330. The first through via 340a and the third through via 340c may be spaced apart along the second direction D2 by the insulating structure 330, and the second through via 340b and the fourth through via 340d may be spaced apart along the second direction D2 by the insulating structure 330.

From a planar perspective, the first to fourth through vias 340a, 340b, 340c, and 340d may have a symmetrical shape with respect to the insulating structure 330.

According to some implementations, in a planar view, the insulating structure 330 has a first length D_330 along the first direction D1 or the second direction D2, and the first length D_330 may be greater than the diameter D_305 of the through via hole. Accordingly, the first to fourth liners 310a, 310b, 310c, and 310d may be completely separated from each other by the insulating structure 330.

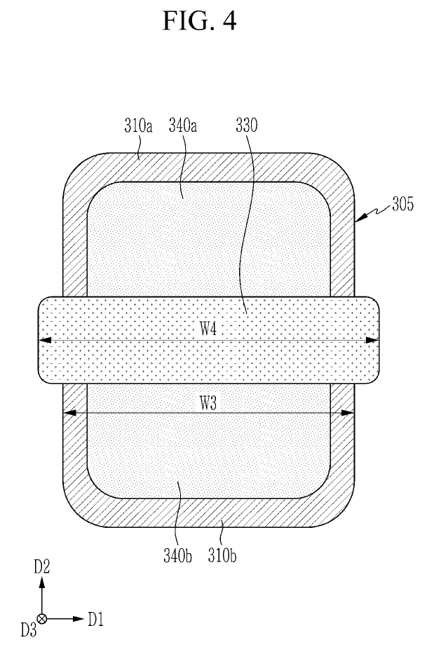

Referring to FIG. 4, a first liner 310a and a second liner 310b, a first through via 340a and a second through via 340b, and an insulating structure 330 positioned between the first through via 340a and the second through via 340b may be positioned inside a through via hole 305.

In some implementations, from a planar perspective, the through via hole 305 may have a roughly rectangular shape. From a planar perspective, the insulating structure 330 may have a linear shape.

In some implementations, from a planar perspective, the first liner 310a and the second liner 310b may be spaced apart along the second direction D2 by the insulating structure 330. Additionally, from a planar perspective, the first through via 340a and the second through via 340b may be spaced apart along the second direction D2 by the insulating structure 330.

According to some implementations, the insulating structure 330 may be positioned approximately at the center of the second direction D2 of the through via hole 305. Accordingly, from a planar perspective, the first through via 340a and the second through via 340b may have symmetrical shapes with respect to the insulating structure.

According to some implementations, the fourth horizontal width W4 of the insulating structure 330 along the first direction D1 in a planar view may be greater than the third horizontal width W3 of the through via hole 305 along the first direction D1. Accordingly, the first liner 310aand the second liner 310b may be completely separated from each other by the insulating structure 330.

According to some implementations, the shape of the through via hole 305 in a planar view and the shape of the insulating structure 330 are not limited to those described above with reference to FIGS. 2 to 4 and may be variously changed.

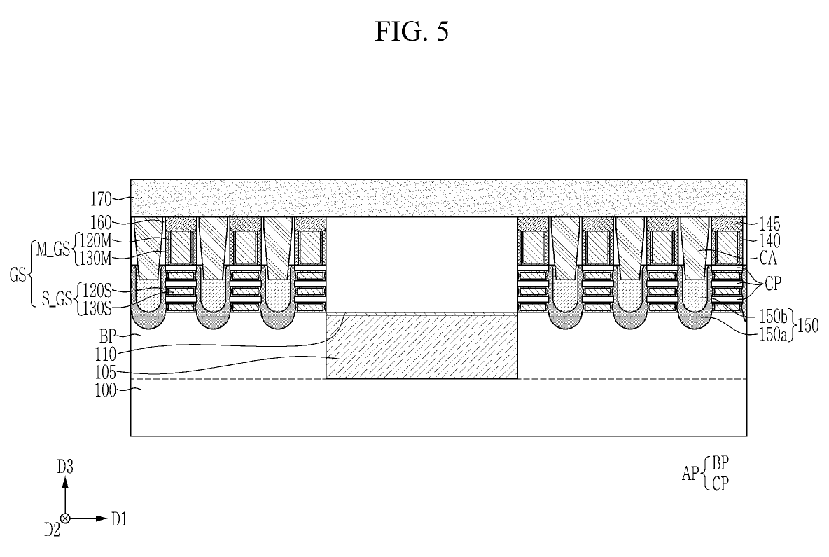

FIGS. 5 to 14 are cross-sectional views illustrating a method for manufacturing a semiconductor device according to some implementations.

Referring to FIG. 5, first, sacrificial layers and active layers are alternately laminated on a substrate 100.

In some implementations, the sacrificial layers may include silicon (Si), germanium (Ge), or silicon-germanium (SiGe), and the active layers may include silicon (Si), germanium (Ge), or silicon-germanium (SiGe). For example, the sacrificial layers may comprise silicon germanium (SiGe), and the active layers may comprise silicon (Si). The concentration of germanium (Ge) in each of the sacrificial layers may be 10 at% to 30 at%.

According to some implementations, mask patterns may be formed on a substrate 100. The mask pattern may have a line shape or a bar shape extending in the second direction D2.

According to some implementations, a trench defining an active pattern AP may be formed by performing a patterning process using mask patterns as an etching mask. Accordingly, an active pattern AP may be formed.

According to some implementations, the active pattern AP may include lower patterns BP and channel patterns CP. Sacrificial layers and channel patterns CP may be alternately stacked on top of the lower pattern BP. In some implementations, the mask pattern may be removed after the active pattern AP is formed.

Next, a field insulating layer 105 is formed to fill the trench on the substrate 100.

For example, the field insulating layer 105 may be formed to cover the entire active pattern AP. Next, the sacrificial layers on top of the lower pattern BP are exposed.

For example, mask patterns are formed on an active pattern AP, and a patterning process is performed using the mask patterns as an etching mask to recess the field insulating layer 105 until the sacrificial layers are exposed.

By this, the upper part of each active pattern AP may be exposed above the field insulating layer 105. In other words, the upper portion of each active pattern AP may protrude in the third direction D3 of the field insulating layer 105.

For example, the field insulating layer 105 may include an insulating material such as a silicon oxide film.

Next, a sacrificial film may be formed on the entire surface of the substrate 100, a hard mask pattern may be formed on the sacrificial film, and the sacrificial film may be patterned using the hard mask pattern as an etching mask to form a sacrificial pattern.

For example, the sacrificial pattern may be formed in a line shape or a bar shape extending in the second direction D2. The sacrificial patterns may be arranged along the first direction D1 at a predetermined pitch. The sacrificial membrane may comprise polysilicon.

Next, a pair of gate spacers 140 may be formed on each of the two sidewalls of the sacrificial pattern.

For example, a gate spacer film may be conformally formed on the entire surface of a substrate 100, and the gate spacer film may be anisotropically etched to form a gate spacer 140.

For example, the gate spacer film may include SiCN, SiCON, SiN, or a combination thereof. Additionally, the gate spacer film may be formed of a multi-layer film including SiCN, SiCON, SiN, or a combination thereof.

Next, recesses may be formed on the upper portion of the active pattern AP, and a source/drain pattern 150 may be formed within the recesses.

For example, a first selective epitaxial growth SEG process may be performed using the inner wall of the recess as a seed layer to form a first source/drain layer 150a. The first source/drain layer 150a may be grown using the active pattern AP exposed by the recess as a seed. For example, the first SEG process may include a chemical vapor deposition (CVD) process or a molecular beam epitaxy (MBE) process.

The first source/drain layer 150a may contain a relatively low concentration of germanium (Ge). As another example, the first source/drain layer 150a may contain only silicon (Si) excluding germanium (Ge).

A second SEG process may be performed on the first source/drain layer 150a to form a second source/drain layer 150b. The second source/drain layer 150bmay be formed to completely fill the recess. The second source/drain layer 150bmay contain a relatively high concentration of germanium (Ge).

The first source/drain layer 150a and the second source/drain layer 150b may form a source/drain pattern 150. During the first and second SEG processes, impurities may be injected in-situ. As another example, after the source/drain pattern 150 is formed, impurities may be injected into the source/drain pattern 150. The source/drain pattern 150 may be doped to have either a first conductivity type (e.g., p-type) or a second conductivity type (e.g., n-type).

Next, an etch stop layer 110 and a first interlayer insulating layer 160 may be sequentially formed on the field insulating layer 105.

According to some implementations, the etch stop layer 110 may be formed on the upper surface of the field insulating layer 105. For example, the etch stop layer 110 may be formed by one of a physical vapor deposition (PVD) process, a chemical vapor deposition (CVD) process, or an atomic layer deposition (ALD) process.

The etch stop layer 110 may include, for example, at least one of silicon nitride (SiN), silicon oxynitride (SiON), silicon carbonate (SiOCN), silicon boron nitride (SiBN), silicon oxyboron nitride (SiOBN), silicon oxycarbide (SiOC), and combinations thereof.

According to some implementations, the first interlayer insulating layer 160 may be positioned on the etch stop layer 110. The first interlayer insulating layer 160 may include a material having an etching selectivity with respect to the etch stop layer 110. For example, the first interlayer insulating layer 160 may include a silicon oxide film.

Next, the sacrificial patterns and sacrificial layers may be removed.

First, exposed sacrificial patterns may be selectively removed. By removing the sacrificial pattern, first empty spaces may be formed exposing the active pattern AP. Through the first empty space, the sacrificial layers of each active pattern AP may be exposed.

Next, the sacrificial layers exposed through the first empty space may be selectively removed.

For example, by performing an etching process that selectively etches the sacrificial layers, only the sacrificial layers may be removed while leaving the channel patterns CP intact. The etching process may have a high etching rate for silicon-germanium having a relatively high germanium concentration. For example, the etching process may have a high etch rate for silicon-germanium having a germanium concentration greater than about 10 at%.

The etching process may be, for example, wet etching. The etchant used in the etching process may quickly remove the sacrificial layer having a relatively high germanium concentration.

By selectively removing the sacrificial layers, only the channel patterns CP may remain on the lower pattern BP. Secondary voids may be formed through the areas where the sacrificial layers have been removed. The second empty spaces may be located between the lower pattern BP and the lowermost channel pattern CP, and between the channel patterns CP.

A gate insulating film 130M and 130S may be formed within the first and second empty spaces.

For example, a gate insulating film 130M and 130S is conformally formed within the first and second empty spaces. For example, the gate insulating film 130Mand 130Smay include a high-k material. In some implementations, an inner spacer may be further formed on the gate insulating film 130M and 130S.

Afterwards, a gate electrode 120M and 120S may be formed on the gate insulating film 130M and 130S. The gate electrode 120M and 120S may be formed to fill the first and second empty spaces.

Next, a capping layer 145 covering the gate electrode 120M and 120S and the gate spacer 140 may be formed. The capping layer 145 may include, for example, at least one of silicon nitride (SiN), silicon oxynitride (SiON), silicon carbon nitride (SiCN), silicon carbonate nitride (SiOCN), and combinations thereof.

Next, a step of forming a contact pattern CA electrically connected to the source/drain pattern 150 by penetrating the first interlayer insulating layer 160 may be further included.

For example, a contact hole may be formed to penetrate the first interlayer insulating layer 160 and expose the source/drain pattern 150. Next, a contact pattern CA is formed that fills the contact hole and is electrically connected to the source/drain pattern 150.

Next, a second interlayer insulating layer 170 covering the capping layer 145, the first interlayer insulating layer 160, and the contact pattern CA may be formed.

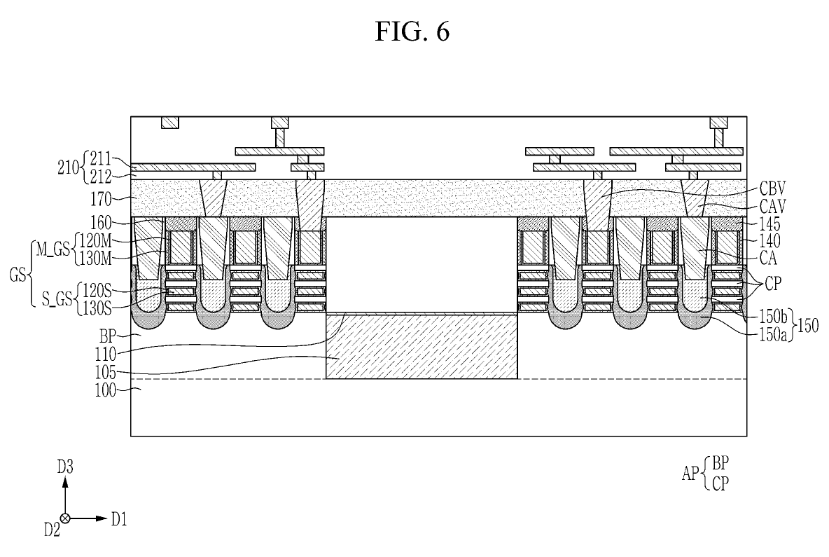

Referring to FIG. 6, a contact via CAV and a gate via CBV penetrating the second interlayer insulating layer 170 may be formed, and an upper wiring structure 210 may be formed on the second interlayer insulating layer 170.

According to some implementations, through holes penetrating the second interlayer insulating layer 170 may be formed, and a contact via CAV and a gate via CBV may be formed to fill each of the through holes. According to some implementations, a contact via CAV may be connected to a contact pattern CA, and a gate via CBV may be connected to a main gate electrode 120M.

Thereafter, an upper insulating layer 212 may be formed over the contact via CAV and the gate via CBV, and upper wirings 211 and upper vias may be formed within the upper insulating layer 212. Accordingly, an upper wiring structure 210 may be formed on the upper surface of the second interlayer insulating layer 170.

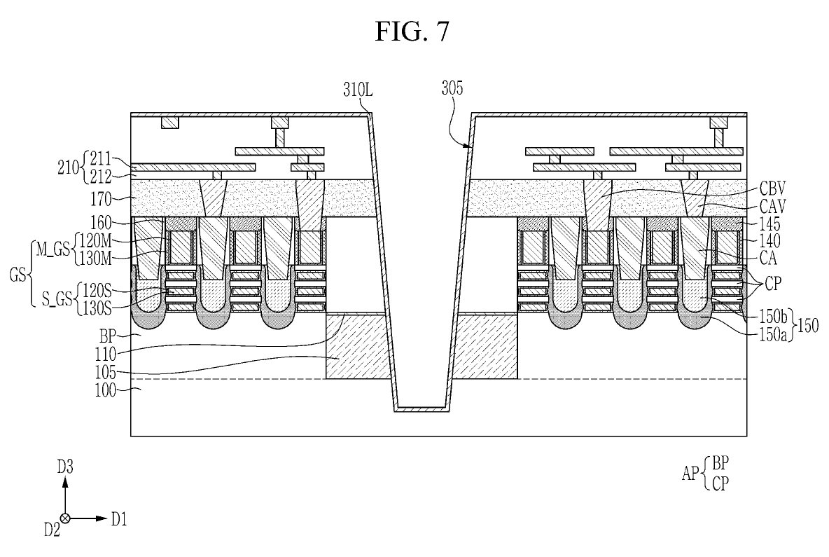

Referring to FIG. 7, a through via hole 305 penetrating the first interlayer insulating layer 160 and the substrate 100 and a liner material layer 310L covering the upper surface of the upper insulating layer 212 may be formed.

In FIG. 7, the through via hole 305 is illustrated as penetrating the first interlayer insulating layer 160, the etch stop layer 110, and the field insulating layer 105, but is not limited thereto. For example, the through via hole 305 may not penetrate the field insulating layer 105.

In some implementations, the through via hole 305 may have a reverse tapered shape. Specifically, the horizontal width of the through via hole 305 may increase as it gets further away from the lower surface of the substrate 100.

According to some implementations, a liner material layer 310L may be formed on the inner surface of the through via hole 305. According to some implementations, the liner material layer 310L may be formed to cover the upper surface of the upper insulating layer 212. For example, the liner material layer 310L may include an oxide.

According to various implementations, the liner material layer 310L may be formed by one of a physical vapor deposition (PVD) process, a chemical vapor deposition (CVD) process, or an atomic layer deposition (ALD) process.

According to some implementations, a liner material layer 310L may be formed on the exposed surface as the through via hole 305 is formed. A liner material layer 310L may be disposed on the bottom surface and inner surfaces of the through via hole 305. That is, the liner material layer 310L may cover the inner wall of the through via hole 305 with a uniform thickness.

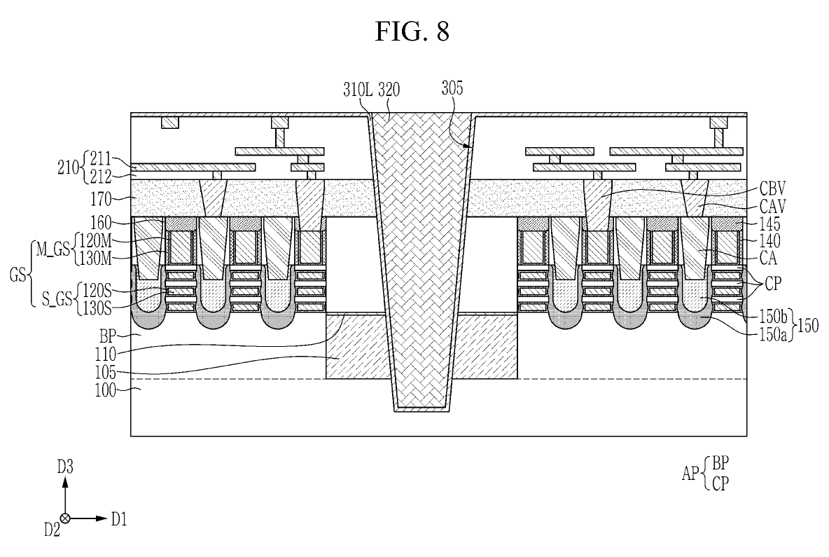

Referring to FIG. 8, a dummy material layer 320 may be formed inside a through via hole 305.

In some implementations, a dummy material may be formed to cover the liner material layer 310L. At this time, the dummy material may fill the inside of the through via hole 305. For example, the dummy material may include a spin on hardmask (SOH).

Next, a flattening process may be performed until the liner material layer 310L is exposed. For example, the planarization process may be performed using a CMP (Chemical Mechanical Polishing) process. As the flattening process is performed, the upper surface of the dummy material may be positioned at substantially the same level as the upper surface of the liner material layer 310L. Accordingly, a dummy material layer 320 may be formed to fill the interior of the through via hole 305.

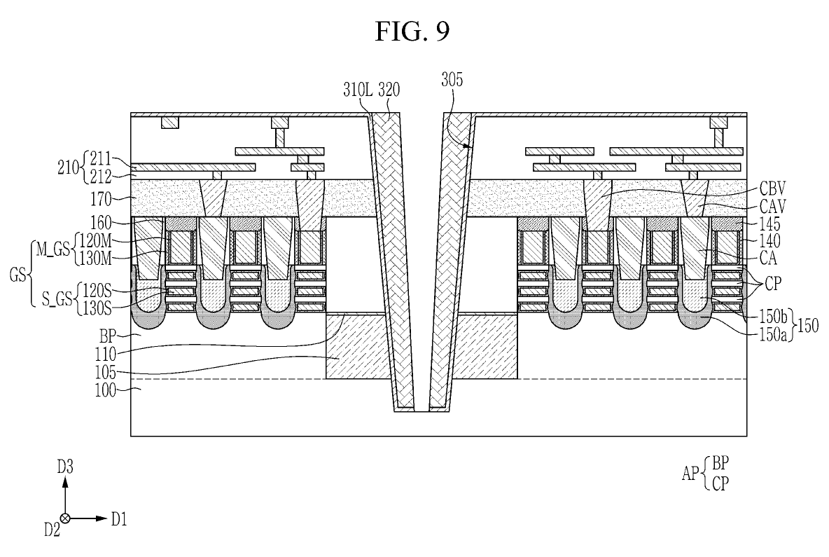

Referring to FIG. 9, a trench in which an insulating structure 330 to be described below is formed may be formed inside a dummy material layer 320.

In some implementations, a portion of the dummy material layer 320 may be removed to form a trench in which an insulating structure 330 is to be formed. In some implementations, the trench may be formed to extend along the through via hole 305 in the third direction D3. The upper surface of the trench may have substantially the same level as the upper surface of the through via hole 305, and the lower surface of the trench may have substantially the same level as the lower surface of the through via hole 305. In other words, the length of the trench along the third direction D3 may be substantially equal to the length of the through via hole 305 along the third direction D3. In some implementations, at least a portion of the liner material layer 310L located on the bottom surface of the through via hole 305 may be removed as the trench is formed.

According to some implementations, the dummy material layers 320 may be spaced apart from each other in the first direction D1 by trenches. The trench may be formed approximately in the center of the first direction D1 of the through via hole 305. Accordingly, in the cross-section along the first direction D1 and the third direction D3, the dummy material layer 320 may have a symmetrical shape with respect to the trench.

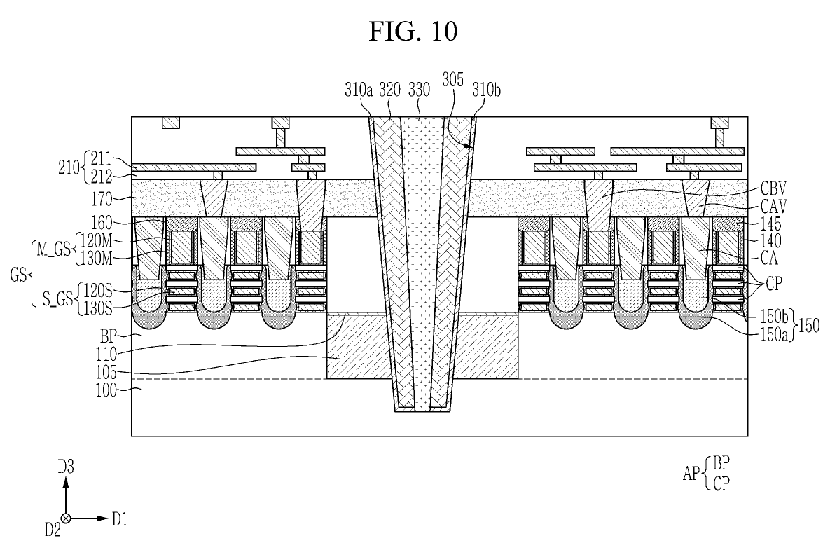

Referring to FIG. 10, an insulating structure 330 may be formed inside a trench.

According to some implementations, an insulating material may be formed to cover the liner material layer 310L and the dummy material layer 320. At this time, insulating material may fill the inside of the trench. For example, the insulating material may include silicon oxide (SiO₂).

In some implementations, the insulating material may comprise the same material or a different material than the liner material layer 310L. Accordingly, the boundary between the insulating material and the liner material layer 310L may be visible or may not be visible and may be formed integrally.

Next, a flattening process may be performed until the upper insulating layer 212 is exposed. For example, the planarization process may be performed using a CMP (Chemical Mechanical Polishing) process. As the flattening process is performed, the upper surface of the insulating material may be positioned at substantially the same level as the upper surface of the upper insulating layer 212. Accordingly, an insulating structure 330 filling the interior of the trench may be formed.

According to some implementations, the insulating structure 330 may be formed to extend along the through via hole 305 in the third direction D3. The upper surface of the insulating structure 330 may have substantially the same level as the upper surface of the through via hole 305, and the lower surface of the insulating structure 330 may have substantially the same level as the lower surface of the through via hole 305. In other words, the length of the insulating structure 330 along the third direction D3 may be substantially equal to the length of the through via hole 305 along the third direction D3.

According to some implementations, the insulating structure 330 may have a reverse tapered shape. Specifically, the horizontal width of the insulating structure 330 may increase as it gets further away from the lower surface of the substrate 100.

According to some implementations, the dummy material layers 320 may be spaced apart from each other in the first direction D1 by an insulating structure 330. The insulating structure 330 may be formed at the center along the first direction D1 of the through via hole 305. Accordingly, in different cross-sections in the first direction D1 and the third direction D3, the dummy material layer 320 may have a symmetrical shape with respect to the insulating structure 330.

In some implementations, the liner material layer 310L covering the upper surface of the upper insulating layer 212 may be removed together while the flattening process is performed. Accordingly, a first liner 310apositioned between the inner surface of the through via hole 305 and one side of the insulating structure 330 and a second liner 310b positioned between the inner surface of the through via hole 305 and the other side of the insulating structure 330 may be formed. As a result, the upper surfaces of the first liner 310a, the second liner 310b, the dummy material layer 320, and the insulating structure 330 may all be positioned at substantially the same level.

According to some implementations, the insulating structure 330 may include the same material or a different material than the first liner 310a and the second liner 310b. Accordingly, the boundary between the insulating structure 330 and the first liner 310a and the boundary between the insulating structure 330 and the second liner 310b may be visible or may not be visible and may be formed integrally.

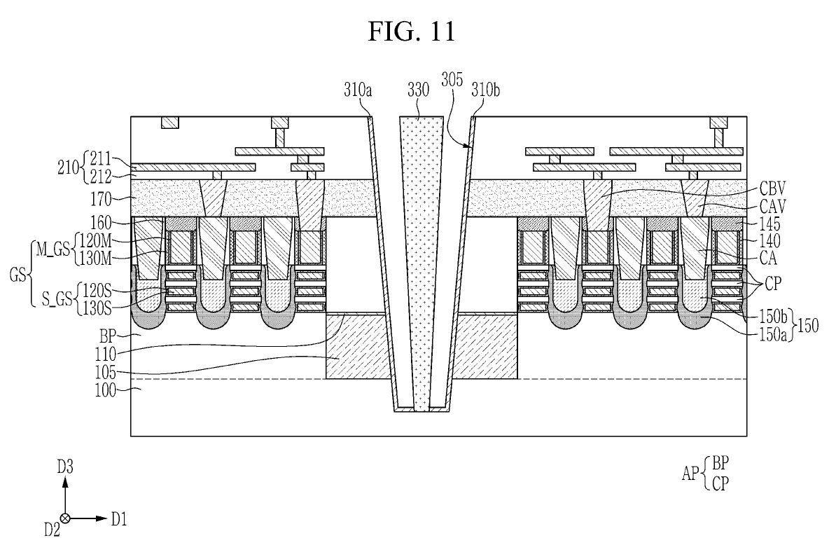

Referring to FIG. 11, the dummy material layer 320 may be removed through an etching process.

For example, the etching process may be wet etching. Also, for example, the etching process may be an isotropic etching. However, the present disclosure is not limited thereto, and the process for removing the dummy material layer 320 may include an ashing process or a strip process.

In some implementations, a void space may be formed between the first liner 310a and the insulating structure 330 as the dummy material layer 320 is removed. Likewise, as the dummy material layer 320 is removed, a void may be formed between the second liner 310band the insulating structure 330.

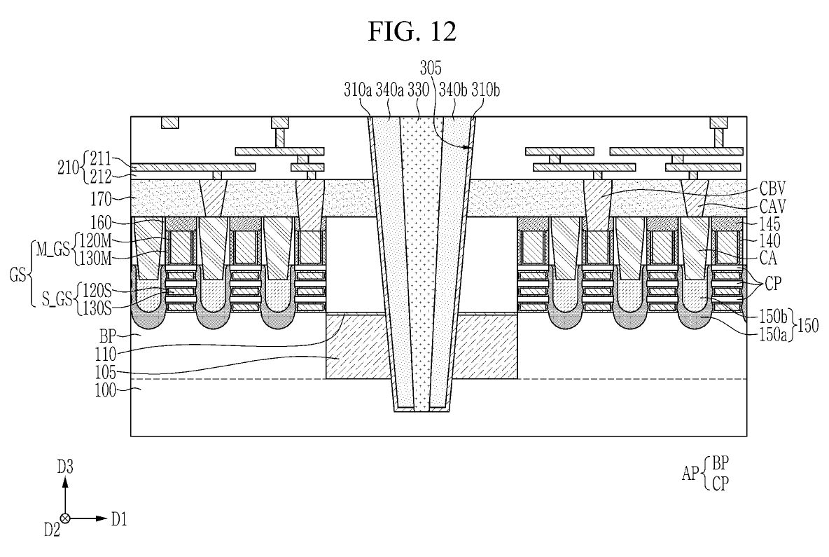

Referring to FIG. 12, a first through via 340a and a second through via 340b may be formed in the empty space formed by removing the dummy material layer 320 illustrated in FIG. 10.

For example, a first through via 340a may be formed between a first liner 310a and an insulating structure 330, and a second through via 340b may be formed between a second liner 310b and an insulating structure 330.

The first through via 340a and the second through via 340b may each include a barrier metal and a conductive pattern. For example, a first through via 340aand a second through via 340b may be formed by sequentially forming a barrier metal and a conductive pattern in the empty space formed by removing the dummy material layer 320 illustrated in FIG. 10. The barrier metal may be formed to surround the sides and bottom of the conductive pattern. For example, the barrier metal may include, but is not limited to, at least one of tantalum (Ta), tantalum nitride (TaN), and combinations thereof. Additionally, for example, the conductive pattern may include, but is not limited to, copper (Cu).

The first through via 340aand the second through via 340bmay each include an insulating liner surrounding the barrier metal. For example, the insulating liner may include silicon oxide (SiO₂). However, this disclosure is not limited thereto, and the first through via 340a and the second through via 340b may not include an insulating liner.

According to some implementations, the first through via 340a and the second through via 340b may be formed to extend along the through via hole 305 in the third direction D3. The upper surfaces of the first through via 340aand the second through via 340b may have substantially the same level as the upper surface of the through via hole 305, and the lower surfaces of the first through via 340a and the second through via 340b may have substantially the same level as the lower surface of the through via hole 305. In other words, the length of each of the first through via 340a and the second through via 340b along the third direction D3 may be substantially equal to the length of the through via hole 305 along the third direction D3.

According to some implementations, the first through via 340a and the second through via 340b may be separated from each other by an insulating structure 330. Specifically, the first through via 340a and the second through via 340b may be spaced apart from each other in the first direction D1 by the insulating structure 330.

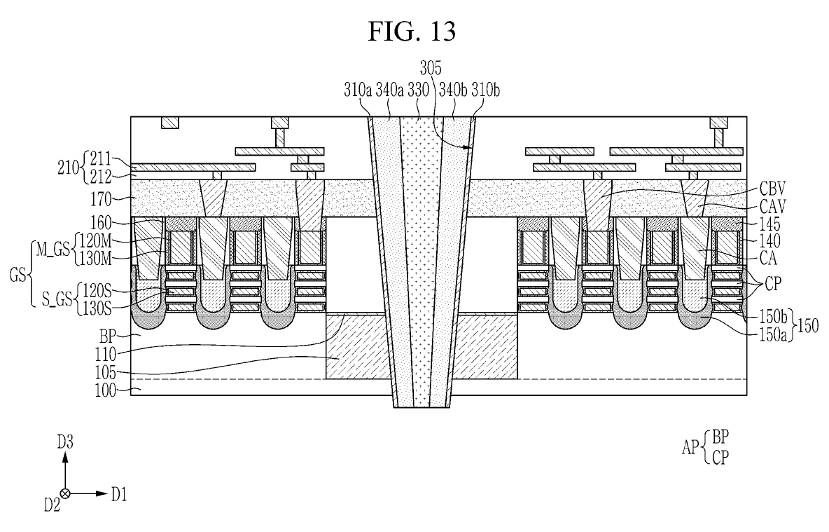

Referring to FIG. 13, at least a portion of the substrate 100 may be removed.

In some implementations, a portion of the substrate 100 may be removed from the lower surface. For example, the substrate 100 may be made relatively thin by removing a certain portion from the lower surface through an etching process.

During the etching process, the first and second liners 310a and 310b, the first and second through vias 340a and 340b, and a portion of the insulating structure 330 may be removed together. As the substrate 100 is partially removed from the lower surface, at least a portion of the first and second liners 310a and 310b, the first and second through vias 340a and 340b, and the insulating structure 330 may be exposed.

Accordingly, the first and second liners 310a and 310b, the first and second through vias 340a and 340b, and the insulating structure 330 may have a shape penetrating the remaining substrate 100.

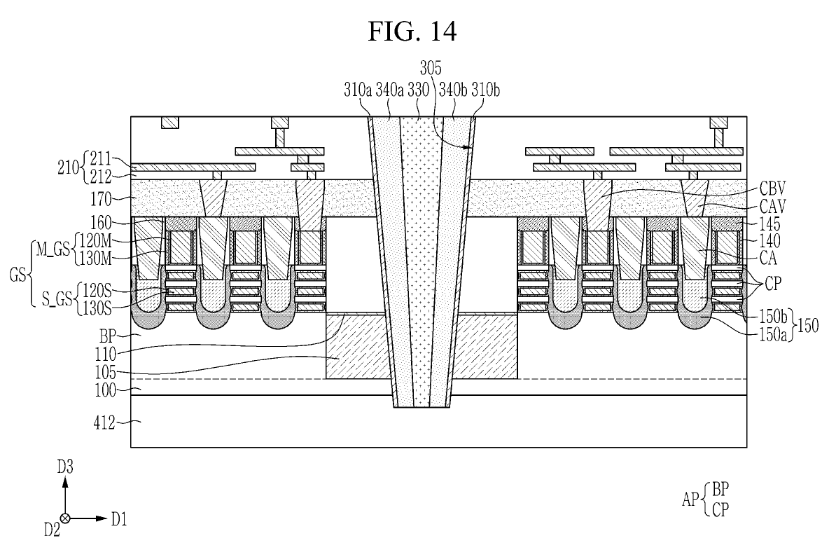

Referring to FIG. 14, a first lower insulating layer 412 may be formed that covers the lower surface of the substrate 100 and the exposed portions of the first and second liners 310a and 310b, the first and second through vias 340a and 340b, and the insulating structure 330.

The space where at least a portion of the substrate 100 and the first and second liners 310a and 310b, the first and second through vias 340a and 340b, and the insulating structure 330 are removed may be filled with an insulating material to form a first lower insulating layer 412.

In some implementations, the first lower insulating layer 412 may fill at least a portion of the space from which the substrate 100 was removed. The first lower insulating layer 412 may be formed to cover the lower surface of the first and second liners 310a and 310b, the first and second through vias 340a and 340b, and the insulating structure 330.

For example, the first lower insulating layer 412 may include at least one of silicon oxide (SiO₂), silicon nitride (SiN), silicon oxynitride (SiON), and a low-k material.

Next, a lower pad 411 as shown in FIG. 1 may be formed inside the first lower insulating layer 412 to form a first lower wiring structure 410 as shown in FIG. 1. The lower pads 411 may be electrically connected to the first through via 340a and the second through via 340b, respectively. The lower pad 411 may be insulated from the substrate 100 by the first lower insulating layer 412.

As the first lower wiring structure 410 is formed, the semiconductor device illustrated in FIG. 1 may be formed. Solder bumps, which are external connection terminals, may be additionally formed on the lower pad 411 as needed. Another semiconductor device may be laminated and bonded on the lower pad 411 as needed.

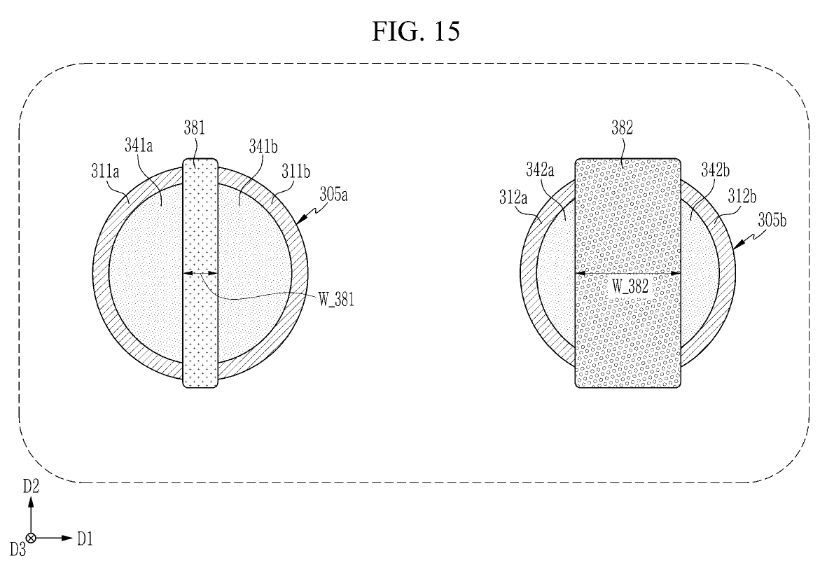

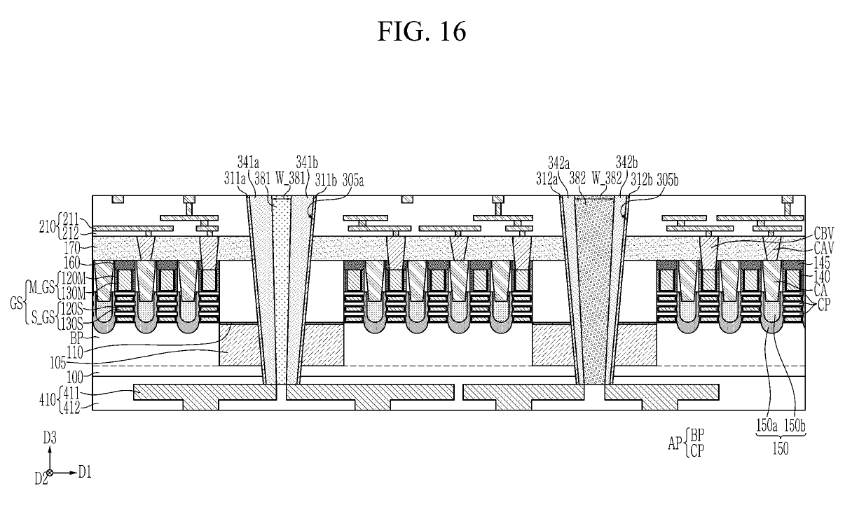

FIG. 15 is a plan view showing through via holes of a semiconductor device according to some implementations. FIG. 16 is a cross-sectional view of a semiconductor device according to some implementations.

The semiconductor devices illustrated in FIGS. 15 and 16 may include components similar to or identical to the semiconductor devices described with reference to FIGS. 1 and 2. However, the semiconductor device in these implementations is different from that illustrated in FIGS. 1 and 2 in that a first through via hole 305a and a second through via hole 305b are positioned on the same substrate, and the horizontal widths of the first insulating structure 381 and the second insulating structure 382 positioned within each of the first through via hole 305a and the second through via hole 305b are different. Here, any overlapping content with that described above in FIGS. 1 and 2 will be briefly explained or omitted, and the differences will be mainly explained.

Referring to FIGS. 15 and 16, a semiconductor device according to some implementations may include a substrate 100, source/drain patterns 150 spaced apart in a first direction D1 on an upper surface of the substrate 100, a channel pattern CP connecting the source/drain patterns 150, a gate electrode 120M and 120S surrounding the channel pattern CP and extending in a second direction D2, a first lower wiring structure 410 positioned on a lower surface of the substrate 100, and a first through via hole 305a and a second through via hole 305b extending through the substrate 100 to the first lower wiring structure 410 in a third direction D3, respectively.

According to some implementations, the semiconductor device may include an first through via of the first group 341a and a second through via of the first group 341b positioned inside the first through via hole 305a and connected to the first lower wiring structure 410, respectively. According to some implementations, the semiconductor device may further include a first insulating structure 381 positioned between an first through via of the first group 341a and a second through via of the first group 341b within the first through via hole 305a.

According to some implementations, the semiconductor device may include a first through via of the second group 342a and a second through via of the second group 342b positioned inside the second through via hole 305b and connected to the first lower wiring structure 410, respectively. According to some implementations, the semiconductor device may further include a second insulating structure 382 positioned between the first through via of the second group 342a and the second through via of the second group 342b within the second through via hole 305b.

According to some implementations, the first insulating structure 381 may have a first width W_381 in the horizontal direction, and the second insulating structure 382 may have a second width W_382 in the horizontal direction. At this time, the first width W_381 of the first insulating structure 381 may be different from the second width W_382 of the second insulating structure 382. For example, the first width W_381 may be smaller than the second width W_382.

In some implementations, the first through via of the first group 341a and the second through via of the first group 341bmay apply power to at least one of the source/drain patterns 150. At this time, the first through via of the first group 341a and the second through via of the first group 341b may be separated and used as different power supply paths. According to some implementations, the first through via of the second group 342a and the second through via of the second group 342b may apply a signal to at least one of the source/drain patterns 150. At this time, the first through via of the second group 342a and the second through via of the second group 342b may be separated and used as different signal transmission paths.

In other words, the width of the first insulating structure 381 positioned between the first through via of the first group 341a and the second through via of the first group 341bthat apply power to at least one of the source/drain patterns 150 may be relatively small. Also, in other words, the width of the second insulating structure 382 positioned between the first through via of the second group 342a and the second through via of the second group 342b that apply a signal to at least one of the source/drain patterns 150 may be relatively large.

Accordingly, the separation distance between the first through via of the first group 341a and the second through via of the first group 341b may be relatively small. The separation distance between the first through via of the second group 342a and the second through via of the second group 342b may be relatively large.

As described above, in the semiconductor device according to the present disclosure, the width of the insulating structure within the through via hole may be formed differently depending on the function of the through via.

Accordingly, in the semiconductor device according to the present disclosure, the signal transmission characteristics may be improved by forming the width of the insulating structure between the signal transmission through vias in a relatively large fashion.

As described above, in the semiconductor device according to the present disclosure, power transmission characteristics may be improved by forming the width of the insulating structure between the power transmission through vias in a relatively small fashion.

As described above, in the semiconductor device according to the present disclosure, the performance of the semiconductor device may be improved by providing a structure optimized for each function of the through via.

According to some implementations, the constituent materials of the first insulating structure 381 and the second insulating structure 382 may be different. For example, the constituent material of the second insulating structure 382 may have a lower dielectric constant than the constituent material of the first insulating structure 381. In other words, the material constituting the second insulating structure 382 between the signal transmission through vias may have a lower dielectric constant than the material constituting the first insulating structure 381 between the power transmission through vias. However, the disclosure is not limited to different materials, and the constituent materials of the first insulating structure 381 and the second insulating structure 382 may be the same.

According to some implementations, the widths of the first insulating structure 381 and the second insulating structure 382 may each increase as they get further away from the first lower wiring structure 410.

According to some implementations, the semiconductor device may further include a first liner of the first group 311a positioned between the first through via of the first group 341a and an inner surface of the first through via hole 305a, and a second liner of the first group 311b positioned between the second through via of the first group 341b and an inner surface of the first through via hole 305a.

According to some implementations, the semiconductor device may further include a first liner of a second group 312a positioned between the inner surface of the first through via of the second group 342a and the second through via hole 305b, and a second liner of the second group 312b positioned between the fourth through via 342b and the inner surface of the second through via hole 305b.

Referring to FIG. 15, in a planar view, the first liner of the first group 311a and the second liner of the first group 311b may be separated by the first insulating structure 381. In some implementations, in a planar view, the first liner of the second group 312a and the second liner of the second group 312b may be separated by the second insulating structure 382.

According to some implementations, from a planar perspective, the first through via of the first group 341a and the second through via of the first group 341b may have symmetrical shapes with respect to the first insulating structure 381. According to some implementations, from a planar perspective, the first through via of the second group 342a and the second through via of the second group 342b may have symmetrical shapes with respect to the second insulating structure 382.

FIG. 17 is a plan view showing a through via hole of a semiconductor device according to some implementations. FIG. 18 is a cross-sectional view of a semiconductor device according to some implementations.

The semiconductor devices illustrated in FIGS. 17 and 18 may include components similar to or identical to the semiconductor devices described with reference to FIGS. 1 and 2. However, the semiconductor device in these implementations has a structure in which the horizontal widths of the first through via 340a and the second through via 340b located within a single through via hole 305 are different, unlike those illustrated in FIGS. 1 and 2. Here, any overlapping content with that described above in FIGS. 1 and 2 will be briefly explained or omitted, and the differences will be mainly explained.

Referring to FIGS. 17 and 18, a semiconductor device according to some implementations may include a first liner 310a, a second liner 310b, a first through via 340a, a second through via 340b positioned within a through via hole 305, and an insulating structure 330 positioned between the first through via 340a and the second through via 340b.

Referring to FIG. 17, from a planar perspective, the first through via 340a and the second through via 340b may not have symmetrical shapes with respect to the insulating structure 330. In other words, the insulating structure 330 may not be located in the center of the through via hole 305. For example, from a planar perspective, the first width W_340a of the first through via 340a may be larger than the second width W_340b of the second through via 340b.

Referring to FIG. 18, in the cross-sections along the first direction D1 and the third direction D3, the first width W_340a of the first through via 340a at the same level may be larger than the second width W_340bof the second through via 340b. In this case, the first through via 340amay apply power to at least one of the source/drain patterns 150, and the second through via 340bmay apply a signal to at least one of the source/drain patterns 150. In other words, the horizontal width of the first through via 340athat applies power to at least one of the source/drain patterns 150 may be greater than the horizontal width of the second through via 340b that applies a signal to at least one of the source/drain patterns 150.

In these implementations, the insulating structure 330 may include a low-k material, and the horizontal width of the insulating structure 330 may increase as it gets farther away from the first lower wiring structure 410.

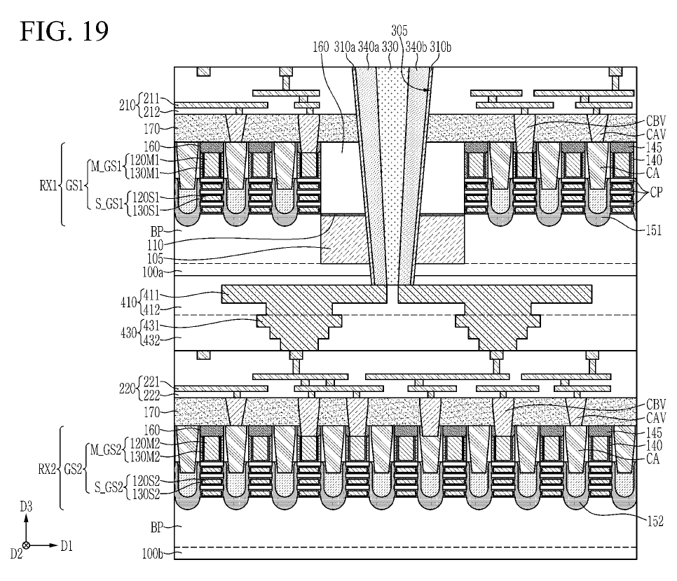

FIG. 19 is a cross-sectional view of a semiconductor device according to some implementations.

The semiconductor device illustrated in FIG. 19 may include components similar to or identical to the semiconductor devices described with reference to FIGS. 1 and 2. However, the semiconductor device in these implementations is different from that illustrated in FIGS. 1 and 2 in that another semiconductor device is bonded to the lower surface of the first lower wiring structure 410. Here, any overlapping content with that described above in FIGS. 1 and 2 will be briefly explained or omitted, and the differences will be mainly explained.

Referring to FIG. 19, a semiconductor device according to some implementations may include a first substrate 100a, a first element RX1 connected to a first upper wiring structure 210 over the first substrate 100a.

According to some implementations, the first upper wiring structure 210 may include first upper wirings 211 and a first upper insulating layer 212 that insulates them.

According to some implementations, the first element RX1 may include a plurality of first gate structures GS1 and first source/drain patterns 151 disposed between the plurality of first gate structures GS1. Each of the plurality of first gate structures GS1 may include a first main gate structure M_GS1 and a plurality of first sub-gate structures S_GS1. The first main gate structure M_GS1 may include a first main gate electrode 120M1 and a first main gate insulating film 130M1. The first sub-gate structure S_GS1 may include a first sub-gate electrode 120S1 and a first sub-gate insulating film 130S1.

According to some implementations, the semiconductor device may further include a first through via 340a, a second through via 340b, each of which extends through the first substrate 100a and is connected to a first lower wiring structure 410 described below, and an insulating structure 330 positioned between the first through via 340a and the second through via 340b. At this time, the horizontal width of the insulating structure 330 may increase as it gets farther away from the first lower wiring structure 410.

According to some implementations, the semiconductor device may further include a first lower wiring structure 410 positioned on a lower surface of the first substrate 100a. According to some implementations, the first lower wiring structure 410 may include lower pads 411 and a first lower insulating layer 412 that insulates them.

According to some implementations, the semiconductor device may further include a bonding structure 430 positioned on a lower surface of the first lower wiring structure 410. According to some implementations, the bonding structure 430 may include bonding pads 431 and a bonding insulating layer 432 that insulates them.

A semiconductor device according to some implementations may include a second substrate 100bpositioned below a bonding structure 430, and a second element RX2 connected to a second upper wiring structure 220 above the second substrate 100b.

According to some implementations, the upper surface of the second upper wiring structure 220 may be in contact with the lower surface of the bonding structure 430. The second upper wiring structure 220 may include second upper wirings 221 and a second upper insulating layer 222 that insulates them.

According to some implementations, the second element RX2 may include a plurality of second gate structures GS2 and second source/drain patterns 152 disposed between the plurality of second gate structures GS2. Each of the plurality of second gate structures GS2 may include a second main gate structure M_GS2 and a plurality of second sub-gate structures S_GS2. The second main gate structure M_GS2 may include a second main gate electrode 120M2 and a second main gate insulating film 130M2. The second sub-gate structure S_GS2 may include a second sub-gate electrode 120S2 and a second sub-gate insulating film 130S2.

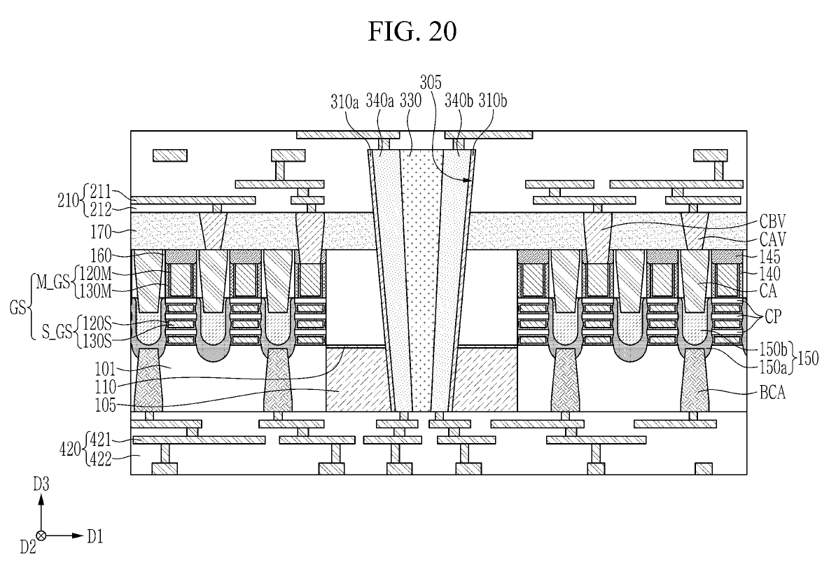

FIG. 20 is a cross-sectional view of a semiconductor device according to some implementations.

The semiconductor device illustrated in FIG. 20 may include components similar to or identical to the semiconductor devices described with reference to FIGS. 1 and 2. However, the semiconductor device in these implementations is different from that illustrated in FIGS. 1 and 2 in that it has a structure in which a first through via 340a and a second through via 340b connect between an upper wiring structure 210 and a second lower wiring structure 420, respectively. Here, any overlapping content with that described above in FIGS. 1 and 2 will be briefly explained or omitted, and the differences will be mainly explained.

A semiconductor device according to some implementations may include an insulating substrate 101 including an insulating material. According to some implementations, the upper surface of the insulating substrate 101 may be formed as a plane parallel to the first direction D1 and a second direction D2 intersecting the first direction D1.

According to some implementations, the semiconductor device may further include an upper wiring structure 210 positioned over a second interlayer insulating layer 170, a second lower wiring structure 420 positioned on a lower surface of the insulating substrate 101, and a lower contact pattern BCA connecting the second lower wiring structure 420 and at least one of the source/drain patterns 150.

According to some implementations, the upper wiring structure 210 may include upper wirings 211, vias, and an upper insulating layer 212. The upper wiring 211 and vias may include metal. An upper insulating layer 212 may be placed between the upper wirings 211 and vias to insulate them. The upper insulating layer 212 may cover the second interlayer insulating layer 170. The upper wiring 211 and vias may be located within the upper insulating layer 212.

The upper wiring structure 210 may be electrically connected to at least one of the main gate electrode 120M and the source/drain pattern 150.

In some implementations, the lower contact pattern BCA may extend through the insulating substrate 101 and be electrically connected to at least one of the source/drain patterns 150. According to some implementations, the lower contact pattern BCA may be positioned adjacent to the sub-gate electrode 120S in the first direction D1. In some implementations, the lower contact pattern BCA may electrically connect at least one of the second lower wiring structure 420 and the source/drain patterns 150.

For example, the lower contact pattern BCA may include at least one of a metal, a metal alloy, a conductive metal nitride, a conductive metal carbide, a conductive metal oxide, a conductive metal carbonitride, and a two-dimensional (2D) material. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CoN), and platinum nitride (PtN).

According to some implementations, the second lower wiring structure 420 may cover the lower surface of the insulating substrate 101. According to some implementations, the second lower wiring structure 420 may include lower wirings 421, vias, and a second lower insulating layer 422. The lower wiring 421 and vias may include metal. A second lower insulating layer 422 may be placed between the lower wirings 421 and vias to insulate them. The lower wiring 421 and vias may be located within the second lower insulating layer 422.

According to some implementations, the semiconductor device may include a first through via 340aconnecting an upper wiring structure 210 and a second lower wiring structure 420. According to some implementations, the semiconductor device may include a second through via 340bconnecting the upper wiring structure 210 and the second lower wiring structure 420. At this time, the first through via 340aand the second through via 340b are positioned within a single through via hole 305, and an insulating structure 330 may be positioned between the first through via 340aand the second through via 340b.

According to some implementations, the insulating structure 330 may have a reverse taper shape whose horizontal width increases as it moves away from the second lower wiring structure 420. Specifically, the horizontal width of the insulating structure 330 may increase as it gets further away from the lower surface of the second lower wiring structure 420. For example, the insulating structure 330 may include, but is not limited to, silicon oxide (SiO₂).

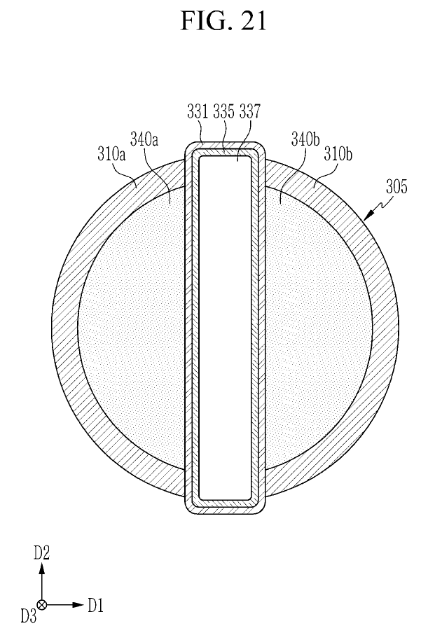

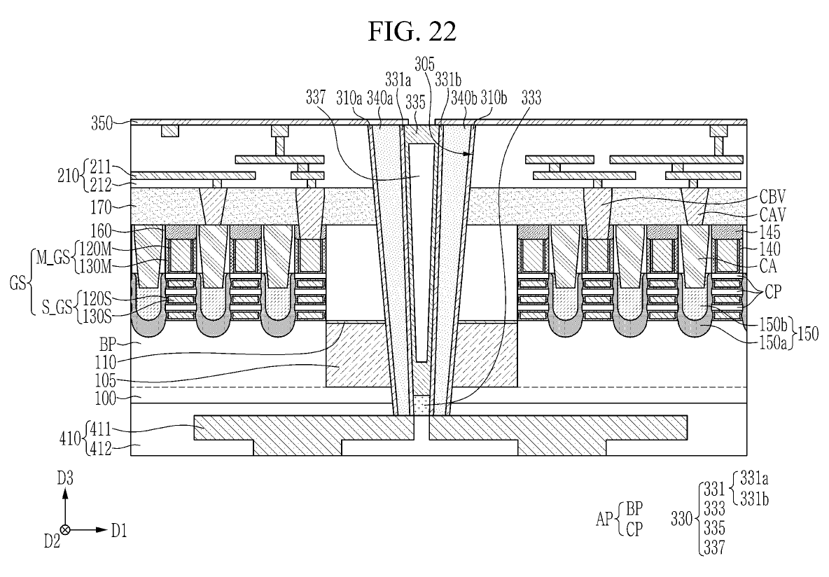

FIG. 21 is a plan view showing a through via hole of a semiconductor device according to some implementations. FIG. 22 is a cross-sectional view of a semiconductor device according to some implementations.

The semiconductor devices illustrated in FIGS. 21 and 22 may include components similar to or identical to the semiconductor devices described with reference to FIGS. 1 and 2. However, the semiconductor device in these implementations has a structure in which the insulating structure 330 includes an air gap 337, unlike that illustrated in FIGS. 1 and 2. Here, any overlapping content with that described above in FIGS. 1 and 2 will be briefly explained or omitted, and the differences will be mainly explained.

Referring to FIGS. 21 and 22, a semiconductor device according to some implementations may include a substrate 100, source/drain patterns 150 spaced apart in a first direction D1 on an upper surface of the substrate 100, a channel pattern CP connecting the source/drain patterns 150, a gate electrode 120M and 120S surrounding the channel pattern CP and extending in a second direction D2, a first lower wiring structure 410 positioned on a lower surface of the substrate 100, and a through via hole 305 extending through the substrate 100 in a third direction D3 to the first lower wiring structure 410.

According to some implementations, the semiconductor device may include a first liner 310a, a second liner 310b, a first through via 340a, and a second through via 340b positioned within a through via hole 305. According to some implementations, the semiconductor device may include an insulating structure 330 positioned between a first through via 340a and a second through via 340b within a through via hole 305.

According to some implementations, the first through via 340a and the second through via 340b are separated by the insulating structure 330, and thus may be used as different paths. For example, the first through via 340a and the second through via 340b may be used as paths for supplying different signals.

According to some implementations, the insulating structure 330 may include an air gap 337, a low-k dielectric film 335 surrounding the air gap 337, an insulating liner 331 surrounding the low-k dielectric film 335, and an oxide layer 333 positioned beneath the low-k dielectric film 335.

From a planar perspective, the first liner 310a and the second liner 310b may be spaced apart along the first direction D1 by the insulating structure 330. Additionally, from a planar perspective, the first through via 340a and the second through via 340b may be spaced apart along the first direction D1 by the insulating structure 330.

According to some implementations, the insulating liner 331 may include a first insulating liner 331apositioned on the inner surface of the first through via 340a and a second insulating liner 331b positioned on the inner surface of the second through via 340b. The first insulating liner 331aand the second insulating liner 331b may extend approximately along the third direction D3 inside the through via hole 305. For example, the first insulating liner 331aand the second insulating liner 331b may include silicon nitride (SiN).

According to some implementations, the distance between the first insulating liner 331a and the second insulating liner 331b may increase as it gets farther away from the first lower wiring structure 410.

According to some implementations, an air gap 337 may be positioned between the first insulating liner 331a and the second insulating liner 331b. The horizontal width of the air gap 337 may increase as it gets further away from the first lower wiring structure 410.

In some implementations, the low-k dielectric film 335 may surround the air gap 337. As the low-k dielectric film 335 surrounds the air gap 337, the air gap 337 may not be exposed. For example, the low-k dielectric film 335 may include a low-k material.

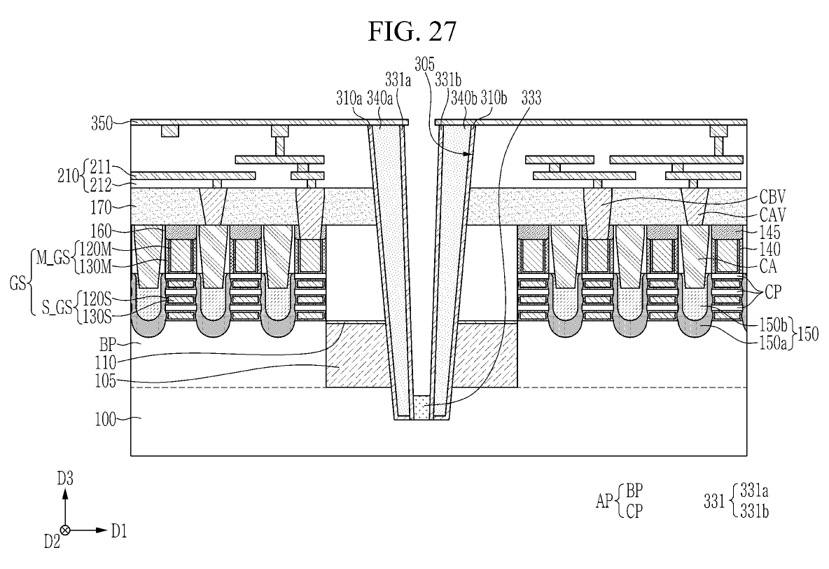

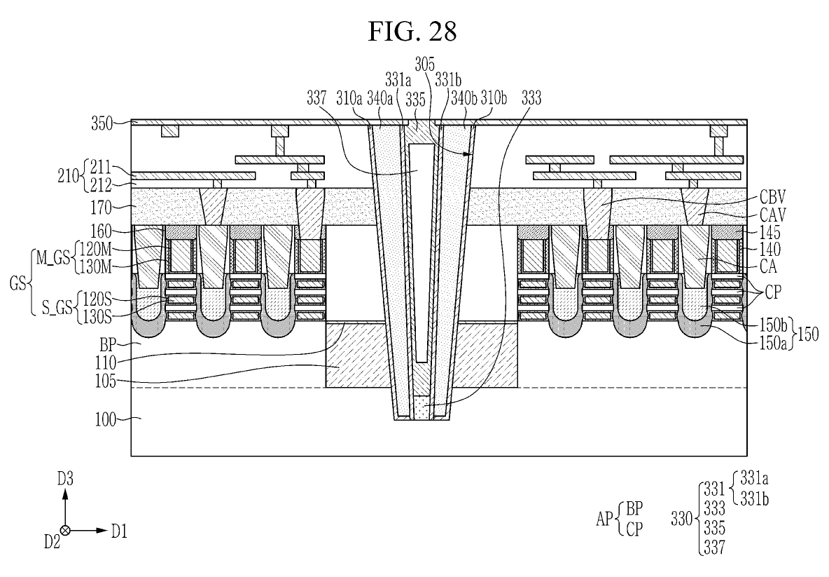

According to some implementations, the oxide layer 333 may be located beneath the air gap 337 between the first insulating liner 331aand the second insulating liner 331b. A low-k dielectric film 335 may be positioned between the oxide layer 333 and the air gap 337. According to some implementations, the insulating structure 330 may not include an oxide layer 333. In other words, the oxide layer 333 may not be located under the air gap 337 between the first insulating liner 331a and the second insulating liner 331b. In this case, instead of the oxide layer 333, a low-k dielectric film 335 may fill the lower portion of the through via hole 305 between the first insulating liner 331a and the second insulating liner 331b. Specific details related to this are described below with reference to FIGS. 27 and 28.

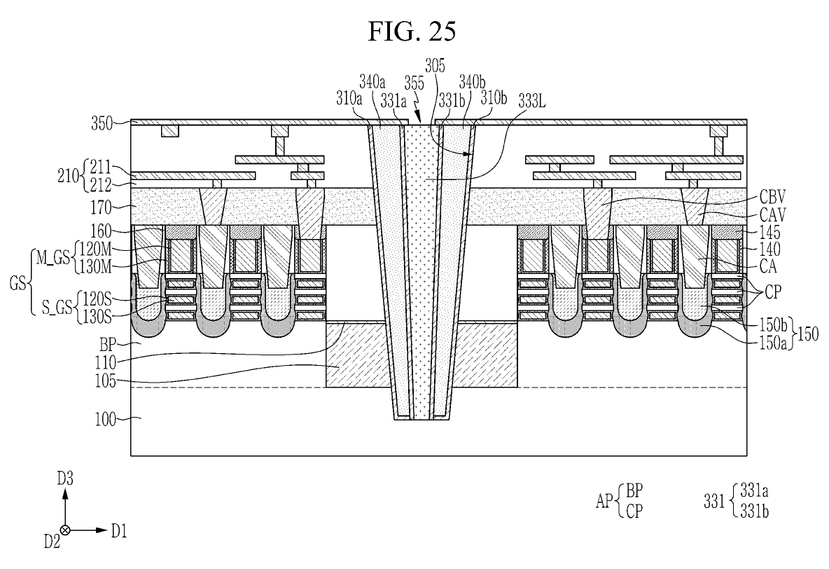

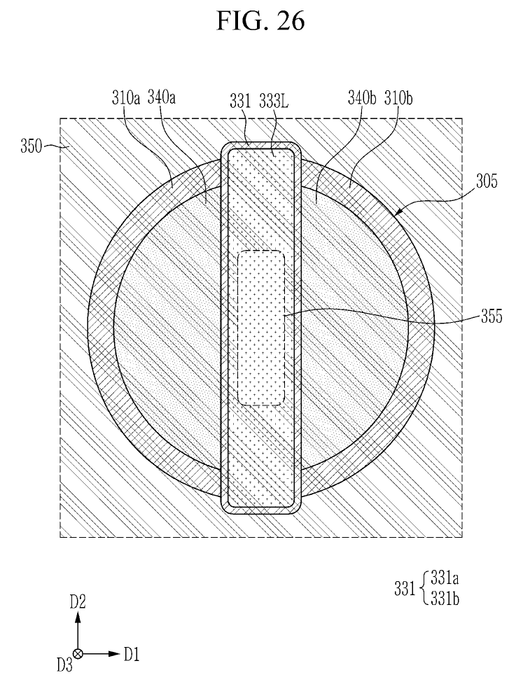

According to some implementations, the semiconductor device may further include a hard mask pattern 350 covering an upper surface of the upper insulating layer 212. According to some implementations, the hard mask pattern 350 may include an opening 355 as described below with reference to FIGS. 25 and 26. For example, the hard mask pattern 350 may be formed to include an opening 355 through a photolithography process. The hard mask pattern 350 may cover the through via hole 305 in an area excluding the opening 355. For example, the hard mask pattern 350 may include silicon nitride (SiN).

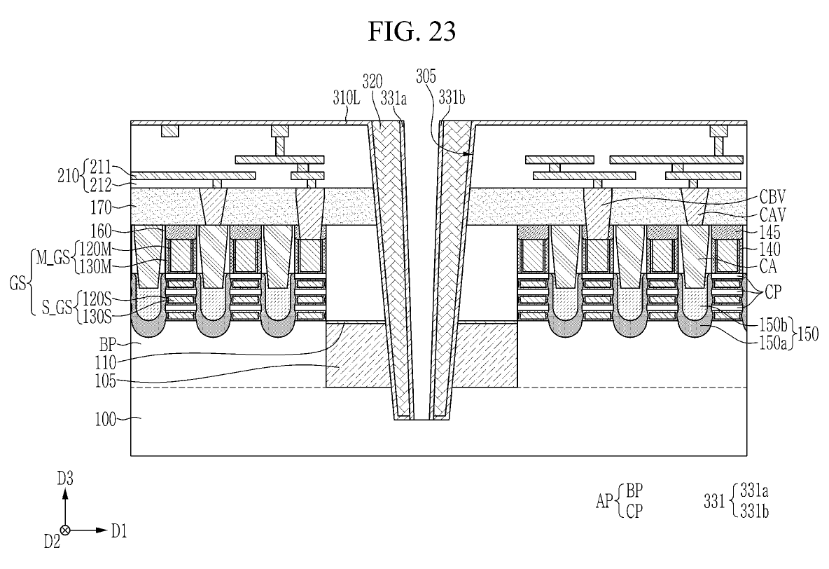

FIGS. 23 to 30 are cross-sectional views illustrating a method for manufacturing a semiconductor device according to some implementations.

Referring to FIG. 23, a through via hole 305 penetrating the first interlayer insulating layer 160 and the substrate 100 and a liner material layer 310L covering the upper surface of the upper insulating layer 212 may be formed.

In FIG. 23, a through via hole 305 is illustrated as extending through the first interlayer insulating layer 160, the field insulating layer 105, and extending into the substrate 100, but is not limited thereto. For example, in some implementations, the through via hole 305 may not extend into the substrate 100. In other words, the through via hole 305 may be formed to extend through the first interlayer insulating layer 160 and extend into the field insulating layer 105.

In some implementations, the through via hole 305 may have a reverse tapered shape. Specifically, the horizontal width of the through via hole 305 may increase as it gets further away from the lower surface of the substrate 100.

According to some implementations, a liner material layer 310L may be formed on the inner surface of the through via hole 305. According to some implementations, the liner material layer 310L may be formed to cover the upper surface of the upper insulating layer 212. For example, the liner material layer 310L may include an oxide.

According to various implementations, the liner material layer 310L may be formed by one of a physical vapor deposition (PVD) process, a chemical vapor deposition (CVD) process, or an atomic layer deposition (ALD) process.

According to some implementations, a liner material layer 310L may be formed on the exposed surface as the through via hole 305 is formed. A liner material layer 310L may be disposed on the bottom surface and inner surfaces of the through via hole 305. That is, the liner material layer 310L may cover the inner wall of the trench with a uniform thickness.

Next, a dummy material layer 320 may be formed inside the through via hole 305.

In some implementations, a dummy material may be formed to cover the liner material layer 310L. At this time, the dummy material may fill the inside of the through via hole 305. For example, the dummy material may include a spin on hardmask (SOH).

Next, a flattening process may be performed until the liner material layer 310L is exposed. For example, the planarization process may be performed using a CMP (Chemical Mechanical Polishing) process. As the flattening process is performed, the upper surface of the dummy material may be positioned at substantially the same level as the upper surface of the liner material layer 310L. Accordingly, a dummy material layer 320 may be formed to fill the interior of the through via hole 305.

Next, a trench may be formed inside the through via hole 305 in which the insulating structure 330 described below is to be formed.

In some implementations, the trench may be formed to extend along the through via hole 305 in the third direction D3. The upper surface of the trench may have substantially the same level as the upper surface of the through via hole 305, and the lower surface of the trench may have substantially the same level as the lower surface of the through via hole 305. In other words, the length of the trench along the third direction D3 may be substantially equal to the length of the through via hole 305 along the third direction D3. In some implementations, at least a portion of the liner material layer 310L located on the bottom surface of the through via hole 305 may be removed as the trench is formed.

According to some implementations, the dummy material layers 320 may be spaced apart from each other in the first direction D1 by trenches. A trench may be formed in the center along the first direction D1 of the through via hole 305. Accordingly, in different cross-sections in the first direction D1 and the third direction D3, the dummy material layer 320 may have a symmetrical shape with respect to the trench.

In some implementations, a layer of insulating liner material may be formed on the exposed surface formed as the trench is formed. The insulating liner material layer may cover the upper surface of the liner material layer 310L and the inner surface of the trench.

In some implementations, at least a portion of the insulating liner material layer may be removed via an anisotropic etching process. For example, a portion of the insulating liner material layer covering the upper surface of the liner material layer 310L and a portion covering the bottom surface of the trench may be removed.

Accordingly, a first insulating liner 331a and a second insulating liner 331b covering the inner side of the trench may be formed. The first insulating liner 331aand the second insulating liner 331b may each cover the exposed side surfaces of the dummy material layers 320 spaced apart from each other.

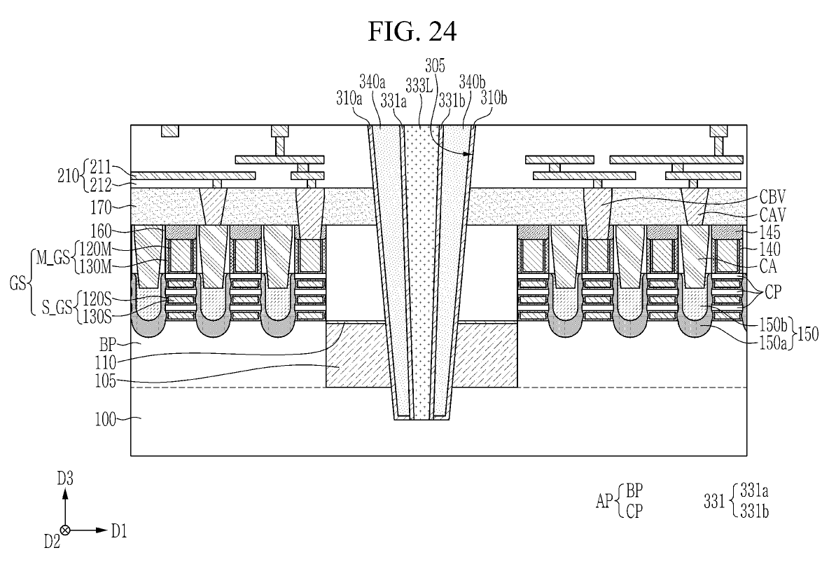

Referring to FIG. 24, after forming an oxide material layer 333L inside the trench and removing the dummy material layer 320, first and second through vias 340a and 340b may be formed.

According to some implementations, an oxide material may be formed to cover the liner material layer 310L, the dummy material layer 320, and the insulating liner 331. At this time, the oxide material may fill the inside of the trench. For example, the oxidizing material may include silicon oxide (SiO₂).

Next, a flattening process may be performed until the upper insulating layer 212 is exposed. For example, the planarization process may be performed using a CMP (Chemical Mechanical Polishing) process. As the flattening process is performed, the upper surface of the oxide material may be positioned at substantially the same level as the upper surface of the upper insulating layer 212. Accordingly, an oxide material layer 333Lfilling the inside of the trench may be formed.

In some implementations, the liner material layer 310L covering the upper surface of the upper insulating layer 212 may be removed together while the flattening process is performed. Accordingly, a first liner 310apositioned between the inner surface of the through via hole 305 and one side of the oxide material layer 333L and a second liner 310b positioned between the inner surface of the through via hole 305 and the other side of the oxide material layer 333L may be formed.

Next, the dummy material layer 320 may be removed through an etching process.

For example, the etching process may be wet etching. Also, for example, the etching process may be an isotropic etching. However, the present disclosure is not limited thereto, and the process for removing the dummy material layer 320 may include an ashing process or a strip process.

In some implementations, a void space may be formed between the first liner 310a and the first insulating liner 331a as the dummy material layer 320 is removed. Likewise, as the dummy material layer 320 is removed, a void may be formed between the second liner 310b and the second insulating liner 331b.

A first through via 340a and a second through via 340b may be formed within the empty spaces formed by removing the dummy material layer 320.

According to some implementations, a first through via 340a may be formed between a first liner 310aand a first insulating liner 331a, and a second through via 340b may be formed between a second liner 310band a second insulating liner 331b.

According to some implementations, the first through via 340a and the second through via 340b may be formed to extend along the through via hole 305 in the third direction D3. The upper surfaces of the first through via 340aand the second through via 340b may have substantially the same level as the upper surface of the through via hole 305, and the lower surfaces of the first through via 340a and the second through via 340b may have substantially the same level as the lower surface of the through via hole 305. In other words, the length of each of the first through via 340a and the second through via 340b along the third direction D3 may be substantially equal to the length of the through via hole 305 along the third direction D3.

According to some implementations, the first through via 340a and the second through via 340b may be separated from each other by an oxide material layer 333L. Specifically, the first through via 340aand the second through via 340b may be spaced apart from each other in the first direction D1 by an oxide material layer 333L.

Referring to FIGS. 25 and 26, a hard mask pattern 350 may be formed on the front surface of the substrate 100.

According to some implementations, the hard mask pattern 350 may include an opening 355. The hard mask pattern 350 may be formed to cover the through via hole 305 in an area excluding the opening 355. For example, the hard mask pattern 350 may include silicon nitride (SiN).

According to some implementations, the opening 355 may overlap the oxide material layer 333Lin the third direction D3. The opening 355 may be located approximately in the center of the oxide material layer 333L.

From a planar perspective, the area of the opening 355 may be smaller than the area of the oxide material layer 333L. For example, the width of the opening 355 along the first direction D1 may be smaller than the width of the oxide material layer 333L along the first direction D1. Additionally, the width of the opening 355 along the second direction D2 may be smaller than the width of the oxide material layer 333L along the second direction D2.

As described above, since the area of the opening 355 included in the hard mask pattern 350 is smaller than the area of the oxide material layer 333L, an air gap 337 may be formed as described below with reference to FIG. 28. Specific details related to this are described below with reference to FIG. 28.

Referring to FIG. 27, at least a portion of the oxide material layer 333L may be removed.

For example, the process of removing the oxide material layer 333L may include an isotropic etching process. Since the oxide material layer 333L includes a material having a high etching selectivity with respect to the insulating liner 331, the insulating liner 331 may be hardly removed while removing the oxide material layer 333L.

In some implementations, at least a portion of the oxide material layer 333L may remain and become the oxide layer 333. For example, the oxide layer 333 may be located at the bottom within the through via hole 305. However, the disclosure is not limited to this arrangement, and the oxide material layer 333L may be completely removed. In other words, the oxide material layer 333Lmay be completely removed, so that a void area extending in the third direction D3 may be formed between the first insulating liner 331aand the second insulating liner 331b. For example, the empty area may expose at least a portion of the substrate 100.

Referring to FIG. 28, a low-k dielectric film 335 may be formed inside a through via hole 305.

According to some implementations, the low-k dielectric film 335 may be formed to cover the upper surface of the hard mask pattern 350. In this case, the planarization process may be performed until the hard mask pattern 350 is exposed. Accordingly, the upper level of the low-k dielectric film 335 may be substantially identical to the upper level of the hard mask pattern 350. However, this disclosure is not limited thereto, and the hard mask pattern 350 may be removed, in which case a planarization process may be performed on the low-k dielectric film 335 until the upper surface of the upper wiring structure 210 is exposed. Accordingly, the upper level of the low-k dielectric film 335 may be substantially the same as the upper level of the upper wiring structure 210.

According to some implementations, the low-k dielectric film 335 may be formed to cover the oxide layer 333 and the insulating liner 331 within the through via hole 305. However, implementations are not limited thereto, and when the oxide material layer 333L is completely removed and the oxide layer 333 is not located as described above with reference to FIG. 27, the low-k dielectric film 335 may cover the insulating liner 331 and fill the lower portion of the through via hole 305.

For example, the low-k dielectric film 335 may include a low-k material.

As described above with reference to FIGS. 25 and 26, since the area of the opening 355 included in the hard mask pattern 350 is smaller than the area of the oxide material layer 333L, the low-k dielectric film 335 may not completely fill the inside of the through via hole 305. The space not filled with the low-k dielectric film 335 inside the through via hole 305 may be referred to as an air gap 337.

In some implementations, the low-k dielectric film 335 may completely surround the air gap 337. As the low-k dielectric film 335 completely surrounds the air gap 337, the air gap 337 may not be exposed.

According to some implementations, as the low-k dielectric film 335 and the air gap 337 are formed, an insulating structure 330 including an insulating liner 331, an oxide layer 333, a low-k dielectric film 335, and an air gap 337 may be formed. Alternatively, according to some implementations, when the oxide material layer 333L is completely removed as described above with reference to FIG. 27, an insulating structure 330 including an insulating liner 331, a low-k dielectric film 335, and an air gap 337 may be formed.

In some implementations, the hard mask pattern 350 may be removed after the insulating structure 330 is formed. However, this disclosure is not limited to the above, and the hard mask pattern 350 may remain without being removed.

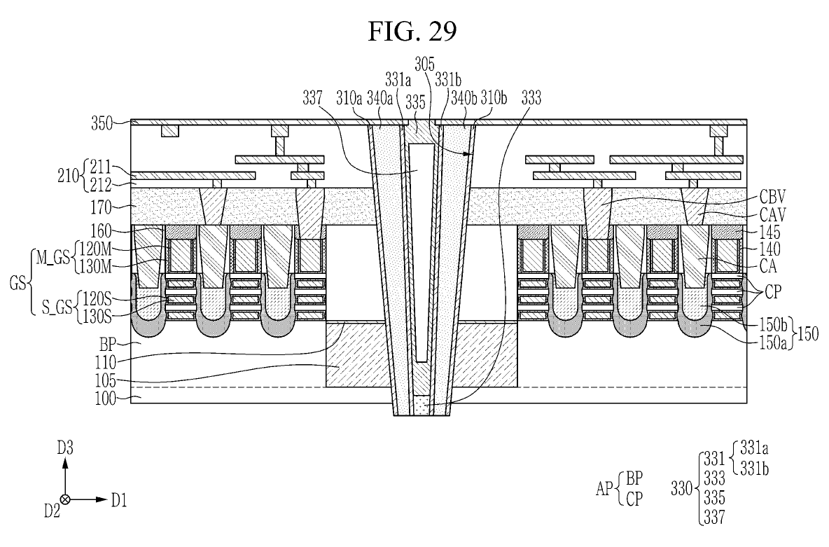

Referring to FIG. 29, at least a portion of the substrate 100 may be removed.

In some implementations, a portion of the substrate 100 may be removed from the lower surface. For example, the substrate 100 may be made thinner by removing a certain portion from the lower surface through an etching process.

During the etching process, the first and second liners 310a and 310b, the first and second through vias 340a and 340b, and a portion of the insulating structure 330 may be removed together. As the substrate 100 is partially removed from the lower surface, at least a portion of the first and second liners 310a and 310b, the first and second through vias 340a and 340b, and the insulating structure 330 may be exposed.

Accordingly, the first and second liners 310a and 310b, the first and second through vias 340a and 340b, and the insulating structure 330 may have a shape penetrating the remaining substrate 100.

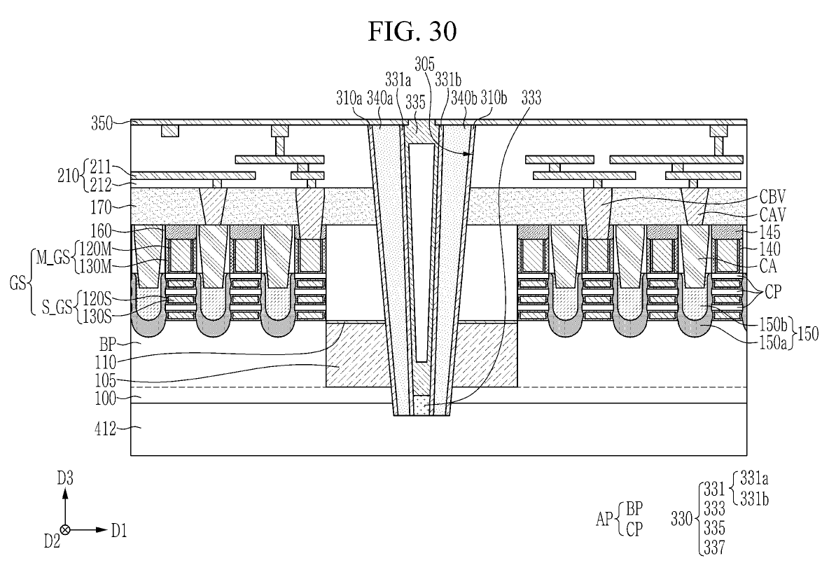

Referring to FIG. 30, a first lower insulating layer 412 may be formed that covers the lower surface of the substrate 100 and the exposed portions of the first and second liners 310a and 310b, the first and second through vias 340a and 340b, and the insulating structure 330.

The space where at least a portion of the substrate 100 and the first and second liners 310a and 310b, the first and second through vias 340a and 340b, and the insulating structure 330 are removed may be filled with an insulating material to form a first lower insulating layer 412.

In some implementations, the first lower insulating layer 412 may fill at least a portion of the space from which the substrate 100 was removed. The first lower insulating layer 412 may be formed to cover the lower surface of the first and second liners 310a and 310b, the first and second through vias 340a and 340b, and the insulating structure 330.

For example, the first lower insulating layer 412 may include at least one of silicon oxide (SiO₂), silicon nitride (SiN), silicon oxynitride (SiON), and a low-k material.

Next, a lower pad 411 as shown in FIG. 22 may be formed inside the first lower insulating layer 412 to form a first lower wiring structure 410 as shown in FIG. 22. The lower pads 411 may be electrically connected to the first through via 340a and the second through via 340b, respectively. The lower pad 411 may be insulated from the substrate 100 by the first lower insulating layer 412.

As the first lower wiring structure 410 is formed, the semiconductor device illustrated in FIG. 22 may be formed. Solder bumps, which are external connection terminals, may be additionally formed on the lower pad 411 as needed. Another semiconductor device may be laminated and bonded on the lower pad 411 as needed.

As described above, in the semiconductor device according to the present disclosure, a low dielectric constant air gap 337 is formed between a plurality of through vias (e.g., the first through via 340a and the second through via 340b of FIGS. 21 and 22), thereby effectively minimizing parasitic capacitance between the through vias.

In addition, as described above, in the semiconductor device according to the present disclosure, parasitic coupling may be reduced by the air gap between the signal transmission through vias (e.g., the first through via 340aand the second through via 340b of FIGS. 21 and 22), thereby improving signal quality.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the present invention have been described in detail above, the scope of the present invention is not limited thereto, and various modifications and improvements made by those skilled in the art using the basic concept of the present invention defined in the following claims also fall within the scope of the present invention.

What is claimed is:

1. A semiconductor device comprising:
a substrate including a first surface and a second surface opposite each other;
source/drain patterns spaced apart in a first direction on the first surface of the substrate;
a channel pattern connecting the source/drain patterns;
a gate electrode surrounding the channel pattern and extending in a second direction intersecting the first direction;
a lower wiring structure on the second surface of the substrate;
a through via hole extending through the substrate to the lower wiring structure in a third direction that intersects the first and second directions;
a first through via and a second through via within the through via hole, wherein each of the first through via and the second through via is independently connected to the lower wiring structure; and
an insulating structure between the first through via and the second through via,
wherein, in a cross-section taken along the first and third directions, a width of the insulating structure increases as a distance from the lower wiring structure increases.

2. The semiconductor device of claim 1, comprising:
a first liner between the first through via and an inner surface of the through via hole; and
a second liner between the second through via and the inner surface of the through via hole,
wherein, in a plan view, the first liner and the second liner are spaced apart by the insulating structure.

3. The semiconductor device of claim 1, wherein,
in a plan view, the insulating structure has a first horizontal width and a second horizontal width greater than the first horizontal width, and
the second horizontal width is greater than a diameter of the through via hole.

4. The semiconductor device of claim 1, wherein the insulating structure includes an air gap extending in the third direction and a low-k dielectric film surrounding the air gap.

5. The semiconductor device of claim 1, wherein,
in a plan view, the first through via and the second through via have a symmetrical shape with respect to the insulating structure.

6. The semiconductor device of claim 1, wherein,
in a cross-section taken along the first and third directions, a first width of the first through via at a first position level along the third direction is greater than a second width of the second through via at the first position along the third direction,
the first through via is arranged to provide power to at least one of the source/drain patterns, and
the second through via is arranged to provide a signal to at least one of the source/drain patterns.

7. The semiconductor device of claim 1, comprising:
an upper wiring structure connected to at least one of the source/drain patterns above the source/drain patterns,
wherein the first through via and the second through via each independently connect the upper wiring structure and the lower wiring structure.

8. The semiconductor device of claim 1, wherein a top surface of the insulating structure, a top surface of the first through via, and a top surface of the second through via are aligned to a same position along the third direction.

9. A semiconductor device comprising:
a substrate including a first surface and a second surface opposite each other;
source/drain patterns spaced apart in a first direction on the first surface of the substrate;
a channel pattern connecting the source/drain patterns;
a gate electrode surrounding the channel pattern and extending in a second direction intersecting the first direction;
a lower wiring structure on the second surface of the substrate;
a through via hole extending through the substrate to the lower wiring structure in a third direction that intersects the first and second directions;
a first through via and a second through via inside the through via hole, whereineach of the first through via and the second through via is independently connected to the lower wiring structure; and
an insulating structure between the first through via and the second through via,
wherein the insulating structure includes a first liner and a second liner respectively contacting the first through via and the second through via, and,
in a cross-section taken along the first and third directions, a distance between the first liner and the second liner increases as a distance from the lower wiring structure increases.

10. The semiconductor device of claim 9, wherein,
in a plan view, the insulating structure has a first horizontal width and a second horizontal width greater than the first horizontal width, and
the second horizontal width is greater than a diameter of the through via hole.

11. The semiconductor device of claim 9, wherein,
in a plan view, the first through via and the second through via have a symmetrical shape with respect to the insulating structure.

12. The semiconductor device of claim 9, comprising:
an upper wiring structure connected to at least one of the source/drain patterns above the source/drain patterns,
wherein the first through via and the second through via each independently connects to the upper wiring structure and to the lower wiring structure.

13. The semiconductor device of claim 9, wherein,
in a plan view, the through via hole has a circular or polygonal shape and is equally divided by the insulating structure.

14. The semiconductor device of claim 9, wherein a top surface of the insulating structure, a top surface of the first through via, and a top surface of the second through via are aligned to a same position along the third direction.

15. A semiconductor device comprising:
a substrate including a first surface and a second surface opposite each other;
source/drain patterns spaced apart in a first direction on the first surface of the substrate;
a channel pattern connecting the source/drain patterns;
a gate electrode surrounding the channel pattern and extending in a second direction intersecting the first direction;
a lower wiring structure on the second surface of the substrate;
a first through via hole and a second through via hole respectively extending through the substrate to the lower wiring structure in a third direction that intersects the first and second directions;
a first through via and a second through via inside the first through via hole, whereineach of the first through via and the second through via is independently connected to the lower wiring structure;
a third through via and a fourth through via inside the second through via hole whereineach of the third through via and the fourth through via is independently connected to the lower wiring structure; and
a first insulating structure between the first through via and the second through via and a second insulating structure between the third through via and the fourth through via,
wherein a first width of the first insulating structure is different from a second width of the second insulating structure.

16. The semiconductor device of claim 15, wherein
the first width of the first insulating structure is smaller than the second width of the second insulating structure,
the first through via and the second through via are arranged to provide power to at least one of the source/drain patterns, and
the third through via and the fourth through via are arranged to provide a signal to at least one of the source/drain patterns.

17. The semiconductor device of claim 15, wherein,
in a cross-section taken along the first and third directions, a width of each of the first insulating structure and the second insulating structure increases as a distance from the lower wiring structure increases.

18. The semiconductor device of claim 15, comprising:
a first liner between the first through via and an inner sidewall of the first through via hole;
a second liner between the second through via and the inner sidewall of the first through via hole;
a third liner between the third through via and an inner sidewall of the second through via hole; and
a fourth liner between the fourth through via and the inner sidewall of the second through via hole,
wherein, in a plan view, the first and second liners are spaced apart by the first insulating structure, and
the third and fourth liners are spaced apart by the second insulating structure.

19. The semiconductor device of claim 15, wherein,
in a plan view, the first insulating structure has a first horizontal width and a second horizontal width greater than the first horizontal width, and
the second horizontal width is greater than a diameter of the first through via hole, and
the second insulating structure has a third horizontal width and a fourth horizontal width greater than the third horizontal width, and
the fourth horizontal width is greater than a diameter of the second through via hole.

20. The semiconductor device of claim 15, wherein,
in a plan view, the first through via and the second through via have a symmetrical shape with respect to the first insulating structure, and
the third through via and the fourth through via have a symmetrical shape with respect to the second insulating structure.
